(19) United States
(12) Patent Application Publication
(10) Pub. No.: US 2026/0150086 A1
(43) Pub. Date: May 28, 2026

(54) METHOD, APPARATUS, AND SYSTEM FOR SEMANTIC COMMUNICATIONS

(71) Applicant: Huawei Technologies Co., Ltd., Shenzhen (CN)

(72) Inventors: Mengyao Ma, Shenzhen (CN); Yiqun Ge, Ottawa (CA); Jianglei Ma, Ottawa (CA); Qifan Zhang, Kanata (CA)

(21) Appl. No.: 19/427,058

(22) Filed: Dec. 19, 2025

Related U.S. Application Data
(63) Continuation of application No. PCT/CN2023/128883, filed on Oct. 31, 2023.
(60) Provisional application No. 63/509,412, filed on Jun. 21, 2023.

(51) Int. Cl. H04W 68/02; H03M 13/00; H04W 76/14

(52) U.S. Cl. CPC H04W 68/02; H03M 13/6312; H04W 76/14

(57) ABSTRACT

Provided are a sensing communication method, apparatus, and system. An apparatus such as a central device can send tokenization configuration and broadcast or multi-cast or unicast query message(s), so that other apparatus(es) such as one or more sensing devices can obtain the query message(s) and respond with sensing result(s) in response to the obtained query message(s). The sensing result(s) may include at least one piece of sensed data and/or at least one sensing semantic corresponding to sensing token(s) that is determined from at least one sensing token and matches query message(s), where the at least one sensing token is tokenized from at least one sensing semantic based on the tokenization configuration.

### CROSS-REFERENCE TO RELATED APPLICATIONS

This application is continuation of International Application No. PCT/CN2023/128883, filed on Oct. 31, 2023, which claims priority to U.S. Provisional Patent Application No. 63/509,412, filed on Jun. 21, 2023, applications of which are hereby incorporated by reference in their entirety.

### TECHNICAL FIELD

The present disclosure relates generally to the field of sensing communication technologies and, in particular, to a sensing communication method, apparatus, and system.

### BACKGROUND

A sensing function will be integrated into the 6th generation (6G) system. A large number of the sensing user equipments (UEs) or sensing devices will be densely deployed in cities, factories, farms and so on. In addition to mobile phones, sensing devices will become an important type of UEs or devices that claim an arrival of IoT time.

Like internet searching engines, 6G will come up with the counterpart, an internet of thing (IoT) searching engine, in a true physical world. In fact, billions of IoT-based applications such as driverless cars, automation factories, smart cities, and autonomous farms, will heavily depend on an efficient and real-time searching engine in our physical world.

Recently, artificial intelligence (AI) has conquered various intellectual and cognitive domains. Some AI is exploring the cutting edge of our intellectual knowledge in chemistry, gaming, mathematics, and gene engineering. Some other AI is providing a human-level Q&A platform in the digital world; the domain that AI hasn't conquered is real-time physical world. Physical-world AI, in which AI technologies are to penetrate into all the aspects of our society and life, may be built on omnipresent IoT connections thanks to 6G.

More challenging than internet searching engine, real-world searching engine would have to search the physical world in real time over a large scale of physical areas and to deal with a multitude of types of data and information (some may be novel and some may not have been invented yet). Furthermore, green technology, low-energy and low-emission, are also raised as key features of 6G. A sensing device may be battery powered and/or completely powered by solar and wind. It would be costly and impracticable to ask all the sensing devices on a large scale to feedback what they are sensing at the same time. On one hand, the frequent sensing and transmission consumes a sensing device much energy and reduce their battery life time; on the other hand, such a high density of the IoT deployment may block the uplink channels, especially the uplink (UL) bandwidth is more expensive than the downlink (DL) one.

This background information is provided to reveal information believed by the applicant to be of possible relevance to the present disclosure. No admission is necessarily intended, nor should it be construed, that any of the preceding information constitutes prior art against the present disclosure.

### SUMMARY

In a first aspect, the present disclosure provides a sensing communication method, where the method includes:
obtaining a tokenization configuration;
obtaining at least one query message;
tokenizing at least one sensing semantic to at least one sensing token based on the tokenization configuration, where each of the at least one sensing semantic is tokenized to a corresponding sensing token;
determining, from the at least one sensing token, one or more sensing tokens matching one or more query messages; and
sending a sensing result, where the sensing result includes at least one piece of sensed data and/or at least one sensing semantic corresponding to the determined one or more sensing tokens.

Because the at least one sensing semantic may be tokenized to the at least one sensing token based on the tokenization configuration (and/or the query message may also be tokenized to a query token if necessary), and the one or more sensing tokens matching the one or more query messages may be determined from the at least one sensing token, the sensing result including at least one piece of sensed data and/or at least one sensing semantic corresponding to the determined one or more sensing tokens could be sent and obtained, and thus query may be conducted more flexibly and reasonably based on the tokenization configuration, and the privacy would be protected.

In a possible implementation of the first aspect, the tokenization configuration includes at least one of:
at least one tokenization model;
at least one function;
at least one projection matrix;
at least one graph-based or topology-based pruning; or
at least one compression approach.

Because the tokenization configuration may adopt various forms, such as tokenization models, functions, projection matrixes, pruning, or compression approaches, a specific tokenization configuration to be adopted may be determined according to actual needs, and thus flexibility and reasonability of query may be further improved.

In a possible implementation of the first aspect, at least one of a set of tokenization models, a set of functions, a set of projection matrixes, a set of graph-based or topology-based pruning, or a set of compression approaches are configured for multiple tasks, and/or at least one of a set of tokenization models, a set of functions, a set of projection matrixes, a set of graph-based or topology-based pruning, or a set of compression approaches are configured for multiple modalities, and/or at least one of a set of tokenization models, a set of functions, a set of projection matrixes, a set of graph-based or topology-based pruning, or a set of compression approaches are configured for multiple combinations of a task and a modality.

Because a set of tokenization models, a set of functions, a set of projection matrixes, a set of graph-based or topology-based pruning, and/or a set of compression approaches may be configured for multiple tasks and/or multiple modalities, different tokenization models, functions, projection matrixes, pruning and/or compression approaches may be used for different tasks and/or modalities, and thus query may be conducted more flexibly and reasonably according to tasks and/or modalities.

In a possible implementation of the first aspect, each tokenization model of the set of tokenization models, each function of the set of functions, each projection matrix of the set of projection matrixes, each graph-based or topology-based pruning of the set of graph-based or topology-based pruning, or each compression approach of the set of compression approaches corresponds to at least one identifier indicating a task identifier, a modality identifier, or both a task identifier and a modality identifier.

Because each tokenization model, function, projection matrix, pruning, or compression approach may correspond to at least one identifier, the tokenization configuration can be determined for a task with a task identifier, or a modality with a modality identifier, or a combination of task and modality with task and modality identifiers when generating the sensing token, and thus flexibility and reasonability of query may be further improved based on the at least one identifier.

In a possible implementation of the first aspect, the tokenization configuration includes at least one tokenization model; and
the tokenizing at least one sensing semantic to at least one sensing token based on the tokenization configuration includes:
tokenizing each of one or more sensing semantics to a corresponding sensing token based on a corresponding one of the at least one tokenization model.

When the tokenization configuration includes at least one tokenization model, one or more sensing semantics may be tokenized to the corresponding sensing token(s) based on the corresponding tokenization model(s), and thus the query can be conducted more flexibly and reasonably as required.

In a possible implementation of the first aspect, each of the at least one tokenization model is a deep learning model; and
the tokenizing at least one sensing semantic to at least one sensing token based on the at least one tokenization model includes:
inputting each of one or more sensing semantics into a corresponding one of the at least one deep learning model to obtain a corresponding sensing token.

When adopting a deep learning model as the tokenization model, the corresponding sensing token may be obtained by inputting each of one or more sensing semantics into a corresponding deep learning model, and thus the query can be conducted more flexibly and reasonably as required based on the deep learning model.

In a possible implementation of the first aspect, the tokenization configuration includes at least one function; and
the tokenizing at least one sensing semantic to at least one sensing token based on the tokenization configuration includes:
applying, with each of one or more sensing semantics as a function parameter, a corresponding one of the at least one function to obtain a corresponding sensing token.

When the tokenization configuration includes at least one function, a corresponding function may be applied with each of one or more sensing semantics as a function parameter, thereby obtaining a sensing token based on a function, which may be simpler and need less computation resources than some other forms of tokenization configurations, and thus the query can be conducted more flexibly and reasonably as required.

In a possible implementation of the first aspect, the tokenization configuration includes at least one projection matrix; and
the tokenizing at least one sensing semantic to at least one sensing token based on the tokenization configuration includes:
projecting each of one or more sensing semantics onto a sub-space defined by a corresponding one of the at least one projection matrix based on a high-dimensional matrix multiplication to obtain a corresponding sensing token.

When the tokenization configuration includes at least one projection matrix, one or more sensing semantics may each be projected onto the sub-space defined by a corresponding projection matrix based on high-dimensional matrix multiplication to obtain a sensing token, which provides another way for tokenizing sensing semantics, and thus the query can be conducted more flexibly and reasonably as required.

In a possible implementation of the first aspect, each of the at least one sensing semantic is represented by a graph or topology, and the tokenization configuration includes at least one graph-based or topology-based pruning, and
the tokenizing at least one sensing semantic to at least one sensing token based on the tokenization configuration includes:
selecting a subgraph, or a partial topology, or partial parameters from the graph or topology represented by each of one or more sensing semantics based on an approach or criterion defined by a corresponding one of the at least one graph-based or topology-based pruning, to obtain a corresponding sensing token.

When each of the at least one sensing semantic is represented by a graph or topology, the tokenization configuration may include at least one graph-based or topology-based pruning, and tokenization may be performed by selecting a subgraph, or a partial topology, or partial parameters from the graph or topology represented by each of one or more sensing semantics based on an approach or criterion defined by a corresponding graph-based or topology-based pruning, which can realize tokenization of sensing semantics represented by a graph or topology and support query based on graph-represented or topology-represented semantics, and thus the query can be conducted more flexibly and reasonably as required.

In a possible implementation of the first aspect, the tokenization configuration includes at least one compression approach, and
the tokenizing at least one sensing semantic to at least one sensing token based on the tokenization configuration includes:
compressing, based on a corresponding one of at least one compression approach, each of one or more sensing semantics to obtain a corresponding sensing token, where the compression approach includes at least one of transformation, quantization, coefficients selection, or entropy coding.

When the tokenization configuration includes at least one compression approach, a corresponding sensing token may be obtained by compressing each of one or more sensing semantics, based on a corresponding compression approach, which can realize tokenization by compressing, and thus the query can be conducted more flexibly and reasonably according to actual demands.

In a possible implementation of the first aspect, the obtaining a tokenization configuration includes:
obtaining the tokenization configuration via a broadcast message;
obtaining the tokenization configuration via a multicast configuration targeted to a group of first apparatuses; or
obtaining the tokenization configuration via a dedicated message to a first apparatus.

By means of broadcasting or multicasting, a large number of apparatuses may be scheduled rather than one-to-one individual scheduling, the resource consumption can be reduced. By means of unicasting, one-to-one individual scheduling can be achieved for special query dedicated to a specific apparatus.

In a possible implementation of the first aspect, each of the at least one query message corresponds to a task, a modality, or a combination of a task and a modality.

Because each query message may correspond to a task, a modality, or a combination of a task and a modality, the query may be conducted more flexibly and reasonably according to the task and/or modality.

In a possible implementation of the first aspect, each of the at least one query message includes at least one identifier, where the at least one identifier indicates a task identifier, a modality identifier, or both a task identifier and a modality identifier.

In a possible implementation of the first aspect, the obtaining a tokenization configuration includes:
obtaining, for each of the at least one query message and based on the at least one identifier for the each of the at least one query message, at least one tokenization model matching the at least one identifier in the tokenization configuration, at least one function matching the at least one identifier in the tokenization configuration, at least one projection matrix matching the at least one identifier in the tokenization configuration, at least one graph-based or topology-based pruning matching the at least one identifier in the tokenization configuration, or at least one compression approach matching the at least one identifier in the tokenization configuration.

Because each query message may include an identifier, which may include a task identifier and/or a modality identifier, a suitable tokenization model, function, projection matrix, graph-based or topology-based pruning, or compression approach matching the identifier may be efficiently obtained for each query message according to the identifier included in the query message and the identifier corresponding to the tokenization model, function, projection matrix, graph-based or topology-based pruning, or compression approach, and thus a suitable tokenization approach can be obtained for a specific task and/or a specific modality.

In a possible implementation of the first aspect, the at least one piece of sensed data includes at least one piece of raw sensed data, half raw sensed data, or compressed sensed data.

Because the at least one piece of sensed data may include the at least one piece of raw sensed data, half raw sensed data, or compressed sensed data, diversity of sensed data would be obtained.

In a second aspect, the present disclosure provides a sensing communication method, where the method includes:
sending a tokenization configuration;
sending at least one query message; and
obtaining one or more sensing results, where each of the one or more sensing results includes at least one piece of sensed data and/or at least one sensing semantic corresponding to at least one sensing token that is tokenized from at least one sensing semantic based on the tokenization configuration and matches one or more query messages, where each of the at least one sensing semantic is tokenized to a corresponding sensing token.

Because the at least one sensing semantic may be tokenized to the at least one sensing token based on the tokenization configuration (and/or the query message may also be tokenized to a query token if necessary), and the one or more sensing tokens matching the one or more query messages may be determined from the at least one sensing token, the sensing result including at least one piece of sensed data and/or at least one sensing semantic corresponding to the determined one or more sensing tokens could be obtained and sent, and thus query may be conducted more flexibly and reasonably based on the tokenization configuration, and the privacy would be protected.

In a possible implementation of the second aspect, the tokenization configuration includes at least one of:
at least one tokenization model;
at least one function;
at least one projection matrix;
at least one graph-based or topology-based pruning; or
at least one compression approach.

Because the tokenization configuration may adopt various forms, such as tokenization models, functions, projection matrixes, pruning, or compression approaches, a specific tokenization configuration to be adopted may be determined according to actual needs, and thus flexibility and reasonability of query may be further improved.

In a possible implementation of the second aspect, at least one of a set of tokenization models, a set of functions, a set of projection matrixes, a set of graph-based or topology-based pruning, or a set of compression approaches are configured for multiple tasks, and/or at least one of a set of tokenization models, a set of functions, a set of projection matrix, a set of graph-based or topology-based pruning, or a set of compression approaches are configured for multiple modalities, and/or at least one of a set of tokenization models, a set of functions, a set of projection matrixes, a set of graph-based or topology-based pruning, or a set of compression approaches are configured for multiple combinations of a task and a modality.

Because a set of tokenization models, a set of functions, a set of projection matrixes, a set of graph-based or topology-based pruning, and/or a set of compression approaches may be configured for multiple tasks and/or multiple modalities, different tokenization models, functions, projection matrixes, pruning and/or compression approaches may be used for different tasks and/or modalities, and thus query may be conducted more flexibly and reasonably according to tasks and/or modalities.

In a possible implementation of the second aspect, each tokenization model of the set of tokenization models, each function of the set of functions, each projection matrix of the set of projection matrix, each graph-based or topology-based pruning of the set of graph-based or topology-based pruning, or each compression approach of the set of compression approaches corresponds to at least one identifier indicating a task identifier, a modality identifier, or both a task identifier and a modality identifier.

Because each tokenization model, function, projection matrix, pruning, or compression approach may correspond to at least one identifier, the tokenization configuration can be determined for a task with a task identifier, or a modality with a modality identifier, or a combination of task and modality with task and modality identifiers when generating the sensing token, and thus flexibility and reasonability of query may be further improved based on the at least one identifier.

In a possible implementation of the second aspect, the tokenization configuration includes at least one tokenization model, and each of one or more sensing tokens is tokenized from a corresponding sensing semantic based on a corresponding one of the at least one tokenization model.

When the tokenization configuration includes at least one tokenization model, one or more sensing semantics may be tokenized to the corresponding sensing token(s) based on the corresponding tokenization model(s), and thus the query can be conducted more flexibly and reasonably as required.

In a possible implementation of the second aspect, each of the at least one tokenization model is a deep learning model, and each of one or more sensing tokens is tokenized from a corresponding sensing semantic by inputting the corresponding sensing semantic into corresponding one of at least one deep learning model to obtain the each of the at least one sensing token.

When adopting a deep learning model as the tokenization model, the corresponding sensing token may be obtained by inputting each of one or more sensing semantics into a corresponding deep learning model, and thus the query can be conducted more flexibly and reasonably as required based on the deep learning model.

In a possible implementation of the second aspect, the tokenization configuration includes at least one function, and each of one or more sensing tokens is tokenized from a corresponding sensing semantic by applying a corresponding one of at least one function with the corresponding sensing semantic as a function parameter to obtain the each of the at least one sensing token.

When the tokenization configuration includes at least one function, a corresponding function may be applied with each of one or more sensing semantics as a function parameter, thereby obtaining a sensing token based on a function, which may be simpler and need less computation resources than some other forms of tokenization configurations, and thus the query can be conducted more flexibly and reasonably as required.

In a possible implementation of the second aspect, the tokenization configuration includes at least one projection matrix, and each of one or more sensing tokens is tokenized from a corresponding sensing semantic by projecting the corresponding sensing semantic onto a sub-space defined by a corresponding one of the at least one projection matrix based on a high-dimensional matrix multiplication to obtain the each of the at least one sensing token.

When the tokenization configuration includes at least one projection matrix, one or more sensing semantics may each be projected onto the sub-space defined by a corresponding projection matrix based on high-dimensional matrix multiplication to obtain a sensing token, which provides another way for tokenizing sensing semantics, and thus the query can be conducted more flexibly and reasonably as required.

In a possible implementation of the second aspect, each of the at least one sensing semantic is represented by a graph or topology, and the tokenization configuration includes at least one graph-based or topology-based pruning, and each of one or more sensing tokens is tokenized from a corresponding sensing semantic by selecting a subgraph, or a partial topology, or partial parameters from the graph or topology represented by each of the at least one sensing semantic based on an approach or criterion defined by a corresponding one of the at least one graph-based or topology-based pruning, to obtain the each of the at least one sensing token.

When each of the at least one sensing semantic is represented by a graph or topology, the tokenization configuration may include at least one graph-based or topology-based pruning, and tokenization may be performed by selecting a subgraph, or a partial topology, or partial parameters from the graph or topology represented by each of one or more sensing semantics based on an approach or criterion defined by a corresponding graph-based or topology-based pruning, which can realize tokenization of sensing semantics represented by a graph or topology and support query based on graph-represented or topology-represented semantics, and thus the query can be conducted more flexibly and reasonably as required.

In a possible implementation of the second aspect, the tokenization configuration includes at least one compression approach, and each of one or more sensing tokens is tokenized from a corresponding sensing semantic by compressing, using a corresponding one of the at least one compression approach, the corresponding sensing semantic to obtain the each of the at least one sensing token, where the compression approach includes at least one of transformation, quantization, coefficients selection, or entropy coding.

When the tokenization configuration includes at least one compression approach, a corresponding sensing token may be obtained by compressing each of one or more sensing semantics, based on a corresponding compression approach, which can realize tokenization by compressing, and thus the query can be conducted more flexibly and reasonably according to actual demands.

In a possible implementation of the second aspect, the sending a tokenization configuration includes:
sending the tokenization configuration via a broadcast message;
sending the tokenization configuration via a multicast configuration targeted to a group of first apparatuses; or
sending the tokenization configuration via a dedicated message to a first apparatus.

By means of broadcasting or multicasting, a large number of apparatuses may be scheduled rather than one-to-one individual scheduling, the resource consumption can be reduced. By means of unicasting, one-to-one individual scheduling can be achieved for special query dedicated to a specific apparatus.

In a possible implementation of the second aspect, each of the at least one query message corresponds to a task, a modality, or a combination of a task and a modality.

Because each query message may correspond to a task, a modality, or a combination of a task and a modality, the query may be conducted more flexibly and reasonably according to the task and/or modality.

In a possible implementation of the second aspect, each of the at least one query message includes at least one identifier, where the at least one identifier indicates a task identifier, a modality identifier, or both a task identifier and a modality identifier.

In a possible implementation of the second aspect, the at least one identifier for the each of the at least one query message is used for a first apparatus to obtaining, for each of the at least one query message, at least one tokenization model matching the at least one identifier in the tokenization configuration, at least one function matching the at least one identifier in the tokenization configuration, at least one projection matrix matching the at least one identifier in the tokenization configuration, at least one graph-based or topology-based pruning matching the at least one identifier in the tokenization configuration, or at least one compression approach matching the at least one identifier in the tokenization configuration.

Because each query message may include an identifier, which may include a task identifier and/or a modality identifier, a suitable tokenization model, function, projection matrix, graph-based or topology-based pruning, or compression approach matching the identifier may be efficiently obtained for each query message according to the identifier included in the query message and the identifier corresponding to the tokenization model, function, projection matrix, graph-based or topology-based pruning, or compression approach, and thus a suitable tokenization approach can be obtained for a specific task and/or a specific modality.

In a possible implementation of the second aspect, the at least one piece of sensed data includes at least one piece of raw sensed data, half raw sensed data, or compressed sensed data.

Because the at least one piece of sensed data may include at least one piece of raw sensed data, half raw sensed data, or compressed sensed data, diversity of sensed data would be obtained.

In a third aspect, a possible implementation of the present disclosure provides a first apparatus, including various modules configured to execute the sensing communication method according to the first aspect or any possible implementation of the first aspect.

In a fourth aspect, a possible implementation of the present disclosure provides a second apparatus, including various modules configured to execute the sensing communication method according to the second aspect or any possible implementation of the second aspect.

In a fifth aspect, a possible implementation of the present disclosure provides a third apparatus, including a processing circuitry for executing the sensing communication method according to the first aspect or any possible implementation of the first aspect.

In a sixth aspect, a possible implementation of the present disclosure provides a fourth apparatus, including a processing circuitry for executing the sensing communication method according to the second aspect or any possible implementation of the second aspect.

In a seventh aspect, a possible implementation of the present disclosure provides a wireless communication system, including: at least one first apparatus according to the third aspect or any possible implementation of the third aspect or at least one third apparatus according to the fifth aspect; at least one second apparatus according to the fourth aspect or any possible implementation of the fourth aspect or at least one fourth apparatus according to the sixth aspect; and at least one fifth apparatus, where each of the at least one fifth apparatus includes: a sending module, configured to send at least one query message to the at least one second apparatus; and an obtaining module, configured to obtain at least one fused sensing result sent by the at least one second apparatus, where the at least one fused sensing result is generated based on one or more sensing results.

In an eighth aspect, a possible implementation of the present disclosure provides a wireless communication system, including: a first processing circuitry for executing the sensing communication method according to the first aspect or any possible implementation of the first aspect; a second processing circuitry for executing the sensing communication method according to the second aspect or any possible implementation of the second aspect; and a third processing circuitry for executing following steps: sending at least one query message to the second processing circuitry; and obtaining at least one fused sensing result sent by the second processing circuitry, where the at least one fused sensing result is generated based on one or more sensing results.

In a ninth aspect, a possible implementation of the present disclosure provides a computer-readable storage medium storing computer execution instructions which, when executed by a processor, cause the processor to execute the sensing communication method according to the first aspect or any possible implementation of the first aspect or the second aspect or any possible implementation of the second aspect.

In a tenth aspect, a possible implementation of the present disclosure provides a computer program product including computer execution instructions which, when executed by a processor, cause the processor to execute the sensing communication method according to the first aspect or any possible implementation of the first aspect or the second aspect or any possible implementation of the second aspect.

The present disclosure provides a sensing communication method, apparatus, and system. An apparatus such as a central device can send tokenization configuration and broadcast or multi-cast or unicast query message(s), so that other apparatus(es) such as one or more sensing devices can obtain the query message(s) and respond with sensing result(s) in response to the obtained query message(s). The sensing result(s) may include at least one piece of sensed data and/or at least one sensing semantic corresponding to sensing token(s) that is determined from at least one sensing token and matches query message(s), where the at least one sensing token is tokenized from at least one sensing semantic based on the tokenization configuration. Thus, query may be conducted flexibly and reasonably based on the tokenization configuration, and the privacy would be protected.

### BRIEF DESCRIPTION OF DRAWINGS

Reference will now be made, by way of example, to the accompanying drawings which show example embodiments of the present disclosure, and in which:

FIG. 1 is a simplified schematic illustration of a communication system according to one or more example embodiments of the present disclosure.

FIG. 2 is a schematic illustration of an example communication system according to one or more example embodiments of the present disclosure.

FIG. 3 is a schematic illustration of a basic component structure of a communication system according to one or more example embodiments of the present disclosure.

FIG. 4 is a block diagram of a device in a communication system according to one or more example embodiments of the present disclosure.

FIG. 5 is a schematic illustration of a sensing communication scenario according to one or more example embodiments of the present disclosure.

FIG. 6 is a schematic illustration of a plurality of the sensing devices in a sensing communication scenario according to one or more example embodiments of the present disclosure.

FIG. 7 is a schematic illustration of interaction among devices in a sensing communication scenario according to one or more example embodiments of the present disclosure.

FIG. 8 is another schematic illustration of interaction among devices in a sensing communication scenario according to one or more example embodiments of the present disclosure.

FIG. 9 is a schematic flowchart of a sensing communication method according to one or more example embodiments of the present disclosure.

FIG. 10 is another schematic flowchart of a sensing communication method according to one or more example embodiments of the present disclosure.

FIG. 11 is another schematic flowchart of a sensing communication method according to one or more example embodiments of the present disclosure.

FIG. 12 is a schematic illustration of realizing a chain of thoughts according to one or more example embodiments of the present disclosure.

FIG. 13 is another schematic illustration of interaction among devices in a sensing communication scenario according to one or more example embodiments of the present disclosure.

FIG. 14 is another schematic illustration of interaction among devices in a sensing communication scenario according to one or more example embodiments of the present disclosure.

FIG. 15 is a schematic illustration of generating a query message.

FIG. 16 is a schematic illustration of reversing a semantic.

FIG. 17 is a schematic illustration of tokenizing a query semantic into a query token.

FIG. 18 is a schematic illustration of responding to a query token.

FIG. 19 is a schematic illustration of scoring the relevance with tokens.

FIG. 20 is another schematic illustration of responding to a query token.

FIG. 21 is a schematic illustration of scoring a relevance with semantic.

FIG. 22 is another schematic illustration of responding to a query token.

FIG. 23 is a schematic illustration of scoring the relevance with tokens converted from semantics.

FIG. 24 is a schematic illustration of generating query tokens.

FIG. 25 is a schematic illustration of generating query semantics.

FIG. 26 is a schematic illustration of responding to two queries with a common semantization model and two tokenization models.

FIG. 27 is a schematic illustration of responding to two queries with a common semantization model and a common tokenization model.

FIG. 28 is another schematic illustration of responding to two queries with two semantization models and two tokenization models.

FIG. 29 is another schematic illustration of responding to two queries with two semantization models and a common tokenization model.

FIG. 30 is a schematic illustration of responding to two query semantics with a common semantization model and two different tokenization models.

FIG. 31 is a schematic illustration of responding to two query semantics with a common semantization model and a common tokenization model.

FIG. 32 is a schematic illustration of responding to two query semantics with two semantization models and two tokenization models.

FIG. 33 is a schematic illustration of responding to two query semantics with two semantization models and one tokenization model.

FIG. 34 is a schematic illustration of responding to two query semantics with one semantization model without tokenization model.

FIG. 35 is a schematic illustration of responding to two query semantics with two semantization models without tokenization model.

FIG. 36 is a schematic illustration of processing two sensing semantics independently.

FIG. 37 is a schematic illustration of processing one sensing semantic but with two tasks independently.

FIG. 38 is a schematic structural diagram of a first apparatus according to one or more example embodiments of the present disclosure.

FIG. 39 is a schematic structural diagram of a second apparatus according to one or more example embodiments of the present disclosure.

### DESCRIPTION OF EMBODIMENTS

In the following description, reference is made to the accompanying figures, which form part of the present disclosure, and which show, by way of illustration, specific aspects of embodiments of the present disclosure or specific aspects in which embodiments of the present disclosure may be used. It is understood that embodiments of the present disclosure may be used in other aspects and include structural or logical changes not depicted in the figures. The following detailed description, therefore, is not to be taken in a limiting sense, and the scope of the present disclosure is defined by the appended claims.

To assist in understanding the present disclosure, examples of wireless communication systems and devices are described below.

### Example Communication Systems and Devices

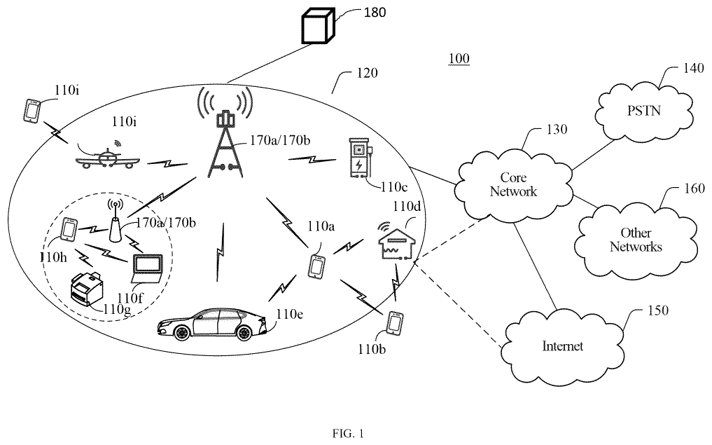

The present disclosure uses the interaction and processing procedures among at least one UE (i.e., the sensing device which is also called sensing node, which is marked as ED in FIG. 1), at least one BS (i.e., the central device) and at least one GPT devices in a wireless system as an illustrative example. The exchanged information and protocol flows can also be used between other network nodes described below, for example, between ED 110 and TRP 170, between ED 110 and core network, between ED 110 and ED 110, between TRP 170 and TRP 170, between TRP 170 and GPT device 180. The UE in the procedure described in the present disclosure may be replaced with a sensing node mentioned below. The BS in the procedure described in the present disclosure may be replaced with a sensing coordinator. Sensing coordinators are nodes in a network that can assist in the sensing operation. These nodes can be stand-alone nodes dedicated to just sensing operations or other nodes (for example TRP 170, ED 110, or core network node shown in FIG. 1) doing the sensing operations in parallel with communication transmissions.

Referring to FIG. 1, as an illustrative example without limitation, a simplified schematic illustration of a communication system according to one or more example embodiments of the present disclosure is provided. The communication system 100 (which may be the wireless system in FIG. 1) includes a radio access network 120. The radio access network 120 may be a next generation (e.g., sixth generation (6G) or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also, the communication system 100 includes a public switched telephone network (PSTN) 140, the internet 150, and other networks 160.

The uplink messages/data transmitted between the central device (e.g., the network node 170) and the sensing device (e.g., ED 110) could be carried in higher layer signaling, such as RRC signaling, or MAC layer signaling. Or, they could be carried in physical layer signaling, e.g., UCI. Or they could be carried in the combination of the higher layer signaling and the physical signaling. It could be noted that the message in the present disclosure could be replaced with information, which may be carried in one single message, or be carried in more than one separate message. The downlink messages/data transmitted between the central device and the ED 110 could be carried in higher layer signaling, such as RRC signaling, or MAC layer signaling. Or, they could be carried in physical layer signaling, e.g., UCI. Or they could be carried in the combination of the higher layer signaling and the physical signaling. It could be noted that the message in the present disclosure could be replaced with information, which may be carried in one single message, or be carried in more than one separate message.

In addition, the communication system 100 includes at least one GPT device 180. The GPT device 180 may be located within the one or more network node 170. The GPT device 180 may be an independent device connected to the network 170, such as an ED 110 which connected to the network node 170 via Uu interface. The GPT device 180 may be a device connected to the network node 170 via core network 130. When the GPT device 180 is an ED, the uplink messages/data transmitted between the central device (e.g., the network node 170) and the GPT device 180 could be carried in higher layer signaling, such as RRC signaling, or MAC layer signaling. Or, they could be carried in physical layer signaling, e.g., UCI. Or they could be carried in the combination of the higher layer signaling and the physical signaling. It could be noted that the message in the present disclosure could be replaced with information, which may be carried in one single message, or be carried in more than one separate message. The downlink messages/data transmitted between the central device and the GPT device 180 could be carried in higher layer signaling, such as RRC signaling, or MAC layer signaling. Or, they could be carried in physical layer signaling, e.g., UCI. Or they could be carried in the combination of the higher layer signaling and the physical signaling. It could be noted that the message in the present disclosure could be replaced with information, which may be carried in one single message, or be carried in more than one separate message.

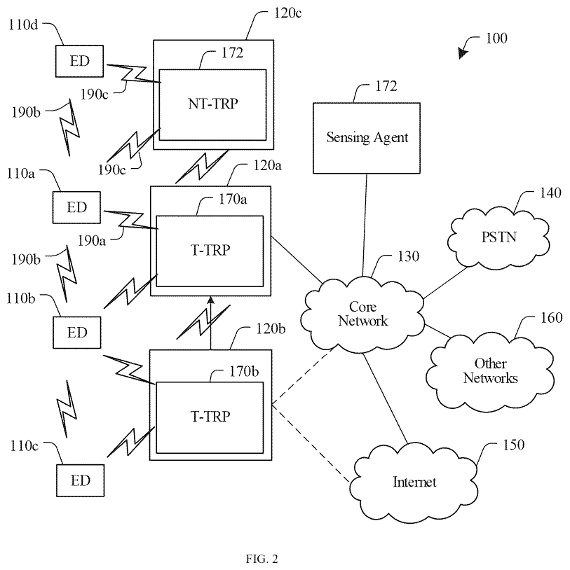

FIG. 2 is a schematic illustration of an example communication system according to one or more example embodiments of the present disclosure, where FIG. 2 illustrates an example communication system 100. In general, the communication system 100 enables multiple wireless or wired elements to communicate data and other content. The purpose of the communication system 100 may be to provide content, such as voice, data, video, signaling and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network including multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered as sub-systems of the communication system. In the example shown in FIG. 2, the communication system 100 includes electronic devices (ED) 110a, 110b, 110c, 110d (generically referred to as ED 110), radio access networks (RANs) 120a-120b, a non-terrestrial communication network 120c, a core network 130, a public switched telephone network (PSTN) 140, the Internet 150, and other networks 160. The RANs 120a-120b include respective base stations (BSs) 170a-170b, which may be generically referred to as terrestrial transmit and receive points (T-TRPs) 170a-170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a-170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), Direct Fourier Transform spread OFDMA (DFT-OFDMA) or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), and User Datagram Protocol (UDP). EDs 110a 110b, and 110c may be multimode devices capable of operation according to multiple radio access technologies and may incorporate multiple transceivers necessary to support such.

### Basic Component Structure

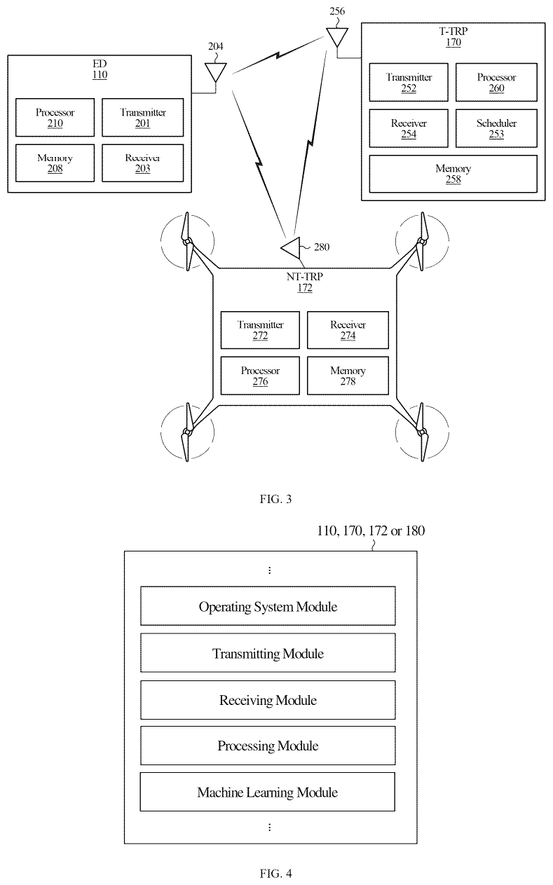

FIG. 3 is a schematic illustration of a basic component structure of a communication system according to one or more example embodiments of the present disclosure, where FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices such as a watch, head mounted equipment, a pair of glasses, an industrial device, or apparatus (e.g., communication module, modem, or chip) in the foregoing devices, among other possibilities. Future generation EDs 110 may be referred to using other terms. Each base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED 110 includes a transmitter 201 and a receiver 203 coupled to one or more antennas 204. Only one antenna 204 is illustrated. One, some, or all of the antennas 204 may alternatively be panels. The transmitter 201 and the receiver 203 may be integrated, e.g., as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to or receiving information from a user, such as through operation as a speaker, a microphone, a keypad, a keyboard, a display, or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., in the memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), a Central Processing Unit (CPU) or an application-specific integrated circuit (ASIC).

In some implementations, the ED 110 may be an apparatus (also called component) for example, communication module, modem, chip, or chipset, it includes at least one processor 210, and an interface or at least one pin. In this scenario, the transmitter 201 and receiver 203 may be replaced by the interface or at least one pin, where the interface or at least one pin is to connect the apparatus (e.g., chip) and other apparatus (e.g., chip, memory, or bus). Accordingly, the transmitting information to the NT-TRP 172 and/or the T-TRP 170 and/or another ED 110 may be referred as transmitting information to the interface or at least one pin, or as transmitting information to the NT-TRP 172 and/or the T-TRP 170 and/or another ED 110 via the interface or at least one pin, and receiving information from the NT-TRP 172 and/or the T-TRP 170 and/or another ED 110 may be referred as receiving information from the interface or at least one pin, or as receiving information from the NT-TRP 172 and/or the T-TRP 170 and/or another ED 110 via the interface or at least one pin. The information may include control signaling and/or data.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a remote radio head, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the foregoing devices or refer to apparatus (e.g., a communication module, a modem, or a chip) in the foregoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming, and generating symbols for transmission. Processing operations related to processing received transmissions in the uplink or over backhaul may include operations such as receiving beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH), and static or semi-static higher layer signaling may be included in a packet transmitted in a data channel, e.g., in a physical downlink shared channel (PDSCH).

The scheduler 253 may be coupled to the processor 260. The scheduler 253 may be included within or operated separately from the T-TRP 170. The scheduler 253 may schedule uplink, downlink, and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same or different one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU, a CPU, or an ASIC.

When the T-TRP 170 is an apparatus (also called as component), for example, communication module, modem, chip, or chipset in a device, it includes at least one processor, and an interface or at least one pin. In this scenario, the transmitter 252 and receiver 254 may be replaced by the interface or at least one pin, where the interface or at least one pin is to connect the apparatus (e.g., chip) and other apparatus (e.g., chip, memory, or bus). Accordingly, the transmitting information to the NT-TRP 172 and/or the T-TRP 170 and/or ED 110 may be referred as transmitting information to the interface or at least one pin, and receiving information from the NT-TRP 172 and/or the T-TRP 170 and/or ED 110 may be referred as receiving information from the interface or at least one pin. The information may include control signaling and/or data.

Although the NT-TRP 172 is illustrated as a drone only as an example, the NT-TRP 172 may be implemented in any suitable non-terrestrial form, such as high altitude platforms, satellite, high altitude platform as international mobile telecommunication base stations and unmanned aerial vehicles, which forms will be discussed hereinafter. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g., MIMO precoding), transmit beamforming, and generating symbols for transmission. Processing operations related to processing received transmissions in the uplink or over backhaul may include operations such as receiving beamforming, demodulating received symbols and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU, a CPU, or an ASIC. In some embodiments, the NT-TRP 172 may actually be a plurality of NT-TRPs that are operating together to serve the ED 110, e.g., through coordinated multipoint transmissions.

When the NT-TRP 172 is an apparatus (e.g., communication module, modem, chip, or chipset) in a device, it includes at least one processor, and an interface or at least one pin. In this scenario, the transmitter 272 and receiver 257 may be replaced by the interface or at least one pin, where the interface or at least one pin is to connect the apparatus (e.g., chip) and other apparatus (e.g., chip, memory, or bus). Accordingly, the transmitting information to the T-TRP 170 and/or another NT-TRP 172 and/or ED 110 may be referred as transmitting information to the interface or at least one pin, and receiving information from the T-TRP 170 and/or another NT-TRP 172 and/or ED 110 may be referred as receiving information from the interface or at least one pin. The information may include control signaling and/or data.

Note that “TRP,” as used herein, may refer to a T-TRP or a NT-TRP. A T-TRP may alternatively be called a terrestrial network TRP (“TN TRP”) and a NT-TRP may alternatively be called a non-terrestrial network TRP (“NTN TRP”).

The T-TRP 170, the NT-TRP 172, and/or the ED 110 may include other components, but these have been omitted for the sake of clarity.

Any or all of the EDs 110 and BS 170 may be sensing nodes in the system 100. Sensing nodes are network entities that perform sensing by transmitting and receiving sensing signals. Some sensing nodes are communication equipment that perform both communications and sensing. However, it is possible that some sensing nodes do not perform communications and are instead dedicated to sensing. The sensing agent 174 is an example of a sensing node that is dedicated to sensing. Unlike the EDs 110 and BS 170, the sensing agent 174 does not transmit or receive communication signals. However, the sensing agent 174 may communicate configuration information, sensing information, signaling information, or other information within the communication system 100. The sensing agent 174 may be in communication with the core network 130 to communicate information with the rest of the communication system 100. By way of example, the sensing agent 174 may determine the location of the ED 110a and transmit this information to the base station 170a via the core network 130. Although only one sensing agent 174 is shown in FIG. 2, any number of sensing agents may be implemented in the communication system 100. In some embodiments, one or more sensing agents may be implemented at one or more of the RANS 120.

A sensing node may combine sensing-based techniques with reference signal-based techniques to enhance UE pose determination. This type of sensing node may also be known as a sensing management function (SMF). In some networks, the SMF may also be known as a location management function (LMF). The SMF may be implemented as a physically independent entity located at the core network 130 with connection to the multiple BSs 170. In other aspects of the present application, the SMF may be implemented as a logical entity co-located inside a BS 170 through logic carried out by the processor 260.

Although not presented in FIG. 3, a GPT device 180 may be included, which has similar structure to ED 110, e.g., GPT device 180 includes at least one processor, a transmitter and a receiver.

### Basic Module Structure

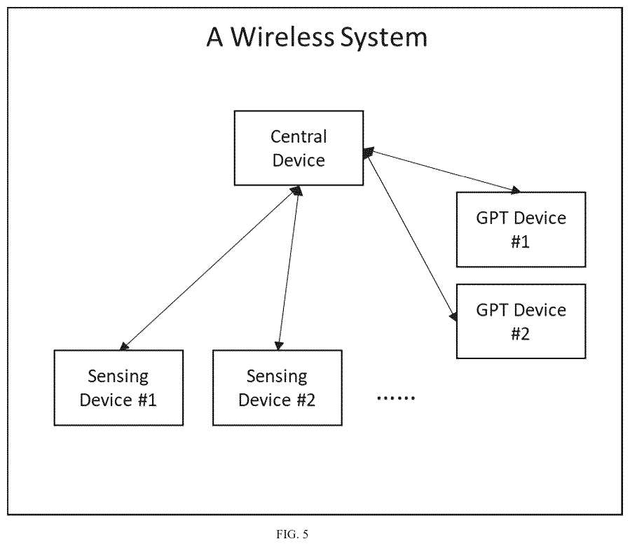

FIG. 4 is a block diagram of a device in a communication system according to one or more example embodiments of the present disclosure, where one or more steps of the embodiment methods provided herein may be performed by corresponding units or modules, according to FIG. 4. FIG. 4 illustrates units or modules in a device, such as in the ED 110, in the T-TRP 170, in the NT-TRP 172, or in the GPT device 180. For example, a signal may be transmitted by a transmitting unit or by a transmitting module. A signal may be received by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU, a CPU, or an ASIC. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation. The transmitter mentioned with reference to FIG. 3 may be a detailed implementation for the transmitting module. The receiver mentioned with reference to FIG. 3 may be a detailed implementation for the receiving module. The processor mentioned with reference to FIG. 3 may be a detailed implementation for the processing module.

Additional details regarding the EDs 110, the T-TRP 170, the NT-TRP 172 and the GPT device 180 are known to those of skill in the art. As such, these details are omitted here.

The details of the present disclosure will be elaborated in the following description.

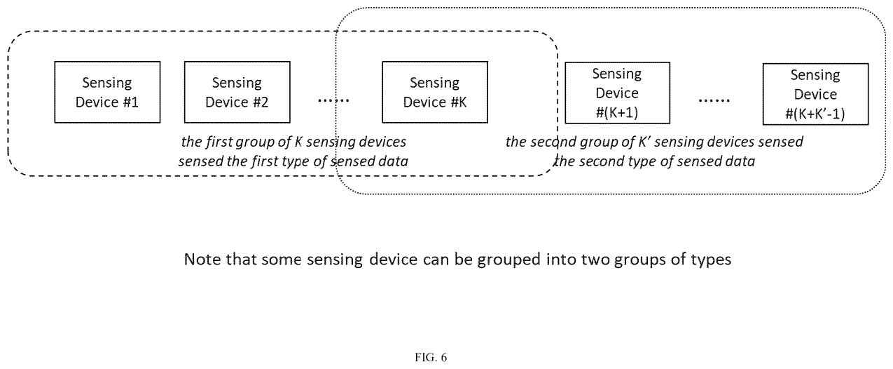

FIG. 5 is a schematic illustration of a sensing communication scenario according to one or more example embodiments of the present disclosure, where a wireless system includes a number of sensing devices, GPT device, and a central device.

In present disclosure, the wireless system is also called communication system, or wireless communication system. Herein the wireless system includes a plurality of devices, for example, the plurality of devices include at least a central device, a plurality of distributed sensing devices and at least a GPT device (in FIG. 5).

The GPT device is responsible for encoding or decoding query messages and sensed data. In details, it generates a query message that contains one goal or goals in natural language for the central device; the central device semantizes the query message into a semantic vector, tokenizes the semantic vector into a goal semantic token (vector), and then broadcasts the goal token to the sensing devices. A sensing device, triggered by receiving the goal semantic token, measures its sensed data and converts the sensed data into a sensed semantic token. The sensing device compares and scores the relevance between the goal semantic token and sensed semantic token and transmit the sensed data in semantic vector only if the score of relevance is higher than a threshold. The central device fuses the sensed data in semantic vectors and output the fused one to the GPT device that will generate the next query message based on the fused input.

A central device may be a BS, e.g., gNB, or eNB etc., or the central device may be an access point (AP).

A sensing device is responsible for measuring and/or collecting local physical-world data. It may be sensing UE, sensing equipment, IoT equipment, UE, mobile phones, handset, or other equipment. The sensing device may be equipped with a sensing gadget or component to measure local physical-world data near it into a sensed data; the sensing encodes and transmits them to the central device.

A GPT device may generate a sequence of the query messages and receives a fused sensing message from the central device. In the present disclosure, the GPT device could be also called AI agent device, robot device, or smart controlling device.

In some implementations, a sensing device may be a UE, a mobile phone or a handset, wherein independence among any two sensing devices are assumed; thereby, a sensing device may be scheduled individually by the wireless system to which the sensing device is associated; and the sensed data that the sensing device measures may be application-level payload for the wireless system and protocol.

The above scheme of scheduling a sensing device is inefficient in terms of radio bandwidth and energy consumption. For instance, a sensing device blindly keeps transmitting its sensed data to the central device, regardless of whether the sensed data is required or not.

From a higher level perspective, it is better to wake a plurality of sensing devices to measure and transmit only when their sensed data would serve a goal or goals; for example, when a generative pre-trained transformer (GPT) device such as a driverless car, may request the information about the moving obstacles near itself, it is useless to keep transmitting irrelevant information to the driverless car, or to transmit all the moving obstacles nearby to the car when the car is parking on the roadside.

To avoid any missing probability of the information, resources in the wireless system in above implementations may be over-scheduled.

FIG. 6 is a schematic illustration of a plurality of the sensing devices in a sensing communication scenario according to one or more example embodiments of the present disclosure, where sensing devices provide multiple-modality sensed data.

In details, a plurality of the sensing devices herein may be grouped or classified in terms of types of sensed data. The first group of the sensing devices may measure the first type of sensed data (e.g., red, green, blue (RGB) images or video), whereas the second group of sensing devices may measure the second type of sensed data (e.g., Radio RF point-cloud or Lidar Point cloud) as illustrated in FIG. 6.

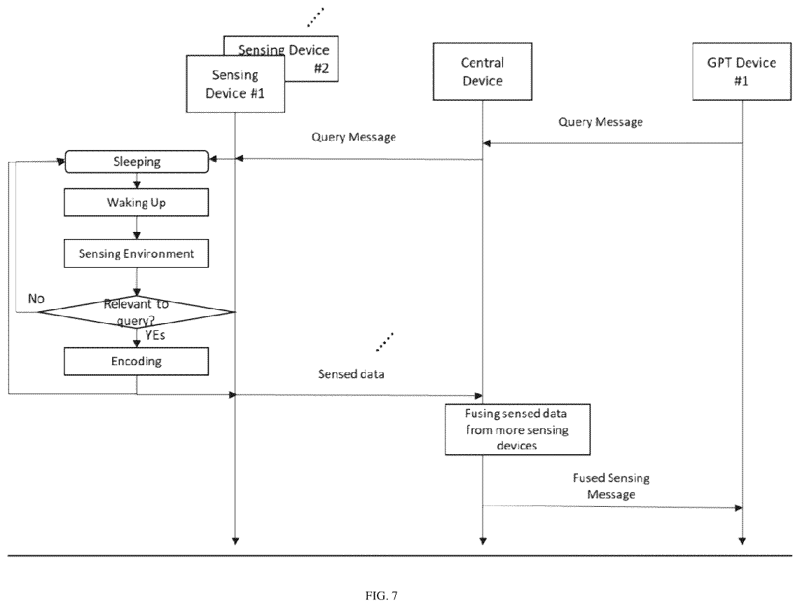

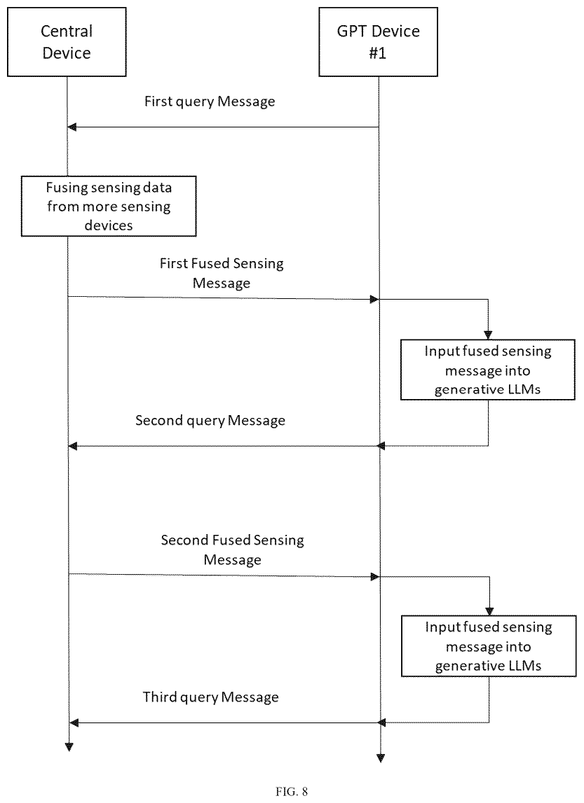

FIG. 7 is a schematic illustration of interaction among devices in a sensing communication scenario according to one or more example embodiments of the present disclosure, where a central device sends a query message to a number of sensing devices and receives the sensed data from the responsive sensing devices.

The central device actively requests or triggers the sensing devices to transmit their most recent sensed data (in FIG. 7). Accordingly, the sensing devices will transmit their sensed data.

The central device may transmit the first query message or messages to one or some sensing devices in DL broadcast, multicast, or unicast channel or channel(s), which may be in physical broadcast channel, shared channel, or dedicated channel(s).

After a sensing device receives the first query message, the sensing device decides whether or not to transmit its sensed data. In details, the sensing device decodes the first query message, measures its data, and decides whether or not to transmit its sensed data, which is called as responding to the first query message. If the sensing device decides to respond to the first query message, the sensing device would encode/encapsulate the sensed data into a payload and then transmit it to the central device in UL channel or channel(s), which may be physical UL shared channel or dedicated UL channel.

After the central device of the wireless system receives all the payloads from the sensing devices that responded to the first query message, the central device may fuse all or some payloads into a fused payload. Optionally, the central device may input the fused payload into the GPT device that may process them and then generate the second query message.

The central device may transmit the second query message or messages to one or some sensing devices in DL broadcast, multicast, or unicast channel or channel(s).

The GPT device transmits the query messages to the central device to inform and configure the central device to schedule when, how, what, and which sensing devices to sense and transmit their sensed data to the central device. The GPT device may be implemented/located together with the central device for shorter latency, or the GPT device may be implemented in a remote data center, to which the central device may access via core network, or the GPT device may be on another connected device in the same wireless system of the central device. Please note that, in the present disclosure, the query message from the central device to the sensing device (downlink message) could be carried in higher layer signaling, such as radio resource control (RRC) signaling, or medium access control (MAC) layer signaling. Or, the query message could be carried in physical layer signaling, e.g., downlink control information (DCI). Or the query message is carried in the combination of the higher layer signaling and the physical signaling. It is similar for other downlink messages/data transmitted from the central device to the sensing device. Similarly, in the present disclosure, for uplink messages/data, they could be carried in higher layer signaling, such as RRC signaling, or MAC layer signaling. Or, they could be carried in physical layer signaling, e.g., uplink control information (UCI). Or they could be carried in the combination of the higher layer signaling and the physical signaling. It could be noted that the message in the present disclosure could be replaced with information, which may be carried in one single message, or be carried in more than one separate message.

FIG. 8 is another schematic illustration of interaction among devices in a sensing communication scenario according to one or more example embodiments of the present disclosure, where the GPT device generates a sequence of query messages and receives a sequence of sensing messages.

The wireless system including a central device, sensing devices, and GPT device may form a series of interactions, in which the GPT device generates a sequence of the query messages for the sensing devices, the sensing devices collect and feedback the sensed data, and the central device fuses them and input them to the GPT device as illustrated in FIG. 8.

In some circumstances, some sensing devices may actively transmit their sensed data without receiving any query message from the central device. The sensing devices that transmit the sensed data may respond to some urgency queries such as fire alarming or car accident. In some sense, some query messages have been pre-defined and configured into the system by default.

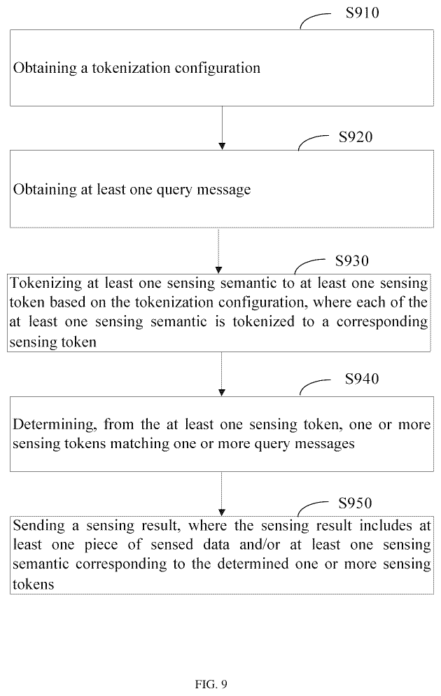

FIG. 9 is a schematic flowchart of a sensing communication method according to one or more example embodiments of the present disclosure. The method can be implemented by a first apparatus. Optionally, the first apparatus can be a sensing device or other device that has similar function (for example, the first apparatus could be a chip), which is not limited herein. As shown in FIG. 9, the method can include the following steps.

S910, obtaining a tokenization configuration.

In details, the first apparatus may obtain the tokenization configuration from a second apparatus in advance so that the first apparatus can token sensing semantic and/or a query message based on the tokenization configuration that is known from both sides of the first apparatus and the second apparatus (where the first apparatus obtains its sensing semantic based on the sensing environment/sensed data). Optionally, the second apparatus can be a central device or other device that has similar function (for example, the second apparatus could be a chip), which is not limited herein.

In a possible implementation, the tokenization configuration may be obtained via a broadcast message, via a multicast message targeted to a group of apparatuses including the first apparatus; or via a dedicated message to the first apparatus.

In details, the first apparatus may obtain the tokenization configuration in different ways. For example, by means of broadcasting or multicasting, a large number of apparatuses may be scheduled rather than one-to-one individual scheduling, the resource consumption can be reduced. By means of unicasting, one-to-one individual scheduling can be achieved for special query dedicated to a specific apparatus.

In a possible implementation, the tokenization configuration may include at least one of: at least one tokenization model; at least one function; at least one projection matrix; at least one graph-based or topology-based pruning; or at least one compression approach.

In details, tokenization may be implemented by using various tokenization models, or functions/approaches for tokenization, where approaches for tokenization may include but not limited to a projection matrix, a graph-based or topology-based pruning, and a compression approach. For example, the tokenization configuration may include one or more tokenization models, or the tokenization configuration may include one or more projection matrixes, or the tokenization configuration may include one or more tokenization models and one or more compression approaches, which is not limited herein. The tokenization configuration may be determined according to actual needs. For example, if there is simple type of query message, the tokenization configuration may include one of at least one tokenization model; at least one function; at least one projection matrix; at least one graph-based or topology-based pruning; or at least one compression approach. Alternatively, if there are multiple complicated types of query messages, the tokenization configuration may include multiple of at least one tokenization model; at least one function; at least one projection matrix; at least one graph-based or topology-based pruning; or at least one compression approach. Whether the tokenization configuration includes one or multiple tokenization manners depends on the specific condition, which is not limited herein. Thus, flexibility and reasonability of query may be further improved based on the tokenization configuration of several kinds of tokenization models, or the functions/approaches as required.

In a possible implementation, at least one of a set of tokenization models, a set of functions, a set of projection matrixes, a set of graph-based or topology-based pruning, or a set of compression approaches are configured for multiple tasks, for multiple modalities, or for multiple combinations of task and modality.

A set of tokenization models, a set of functions, a set of projection matrixes, a set of graph-based or topology-based pruning, and/or a set of compression approaches may be configured for multiple tasks and/or multiple modalities. Taking the tokenization model as an example, tokenization model 1 may correspond to task 1 “find moving obstacles” and tokenization model 2 may correspond to task 2 “localize incoming pedestrians,” which is not limited herein. In this way, query may be conducted more flexibly and reasonably by using various tokenization models, functions, projection matrixes, graph-based or topology-based pruning and/or compression approaches according to tasks and/or modalities.

In a possible implementation, each tokenization model of the set of tokenization models, each function of the set of functions, each projection matrix of the set of projection matrix, each graph-based or topology-based pruning of the set of graph-based or topology-based pruning, or each compression approach of the set of compression approaches corresponds to at least one identifier indicating a task identifier, a modality identifier, or both a task identifier and a modality identifier.

Because each one in the set of tokenization models, the set of functions, the set of projection matrix, the set of graph-based or topology-based pruning, or the set of compression approaches may correspond to at least one identifier, the first apparatus can determine a specific tokenization model or function/approach for a task with a task identifier, or for a modality with a modality identifier, or for a combination of a task and a modality with task and modality identifiers when generating the sensing token. Taking the tokenization model as an example, the tokenization model 1 may correspond to task 1 “find moving obstacles” with task identifier t₁ and the tokenization model 2 may correspond to task 2 “localize incoming pedestrians” with task identifier t₂, which is not limited herein. This flexibility and reasonability of query may be further improved based on the at least one identifier.

As discussed above, the second apparatus may broadcasts/multicasts/unicasts the tokenization configuration to the first apparatus. It is supposed that the abbreviation “f” may be used to represent configured tokenization model, or the function/approach used for tokenization, the abbreviation “o” may be used to represent the sensing semantic, and the abbreviation “c” may be used to represent the sensing token. Therefore the configured tokenization model, or the function/approach f may be used by the first apparatus to tokenize the sensing semantic o into the sensing token c, where the configured tokenization model, or the function/approach f may have several representations, which is discussed below.

In a possible implementation, the tokenization configuration includes at least one tokenization model; and the tokenizing at least one sensing semantic to at least one sensing token based on the tokenization configuration includes: tokenizing each of one or more sensing semantics to a corresponding sensing token based on a corresponding one of the at least one tokenization model. Optionally, each of the at least one tokenization model is a deep learning model; and the tokenizing at least one sensing semantic to at least one sensing token based on the at least one tokenization model includes: inputting each of one or more sensing semantics into a corresponding one of the at least one deep learning model to obtain a corresponding sensing token.

In details, the tokenization configuration may include at least one tokenization model f, which can be a deep learning model, with sensing semantic o as input, and sensing token c as output. Therefore, when adopting a deep learning model as the tokenization model f, the corresponding sensing token c may be obtained by inputting each of one or more sensing semantics o into a corresponding deep learning model f, and thus the query can be conducted more flexibly and reasonably as required based on the deep learning model.

In a possible implementation, the tokenization configuration includes at least one function; and the tokenizing at least one sensing semantic to at least one sensing token based on the tokenization configuration includes: applying, with each of one or more sensing semantics as a function parameter, a corresponding one of the at least one function to obtain a corresponding sensing token.

In details, the tokenization configuration includes at least one function f, which can be c=f(0), i.e., sensing token c will be obtained by applying function f with sensing semantic o as function parameters. Therefore, when the tokenization configuration includes at least one function, a corresponding function may be applied with each of one or more sensing semantics o as a function parameter, thereby obtaining a sensing token c based on a function f, which may be simpler and need less computation resources than some other forms of tokenization configurations, and thus the query can be conducted more flexibly and reasonably as required.

In a possible implementation, the tokenization configuration includes at least one projection matrix; and the tokenizing at least one sensing semantic to at least one sensing token based on the tokenization configuration includes: projecting each of one or more sensing semantics onto a sub-space defined by a corresponding one of the at least one projection matrix based on a high-dimensional matrix multiplication to obtain a corresponding sensing token.

In details, the tokenization configuration includes the at least one projection matrix f, which can be c=fo, i.e., sensing token c will be obtained by projecting sensing semantic o onto a sub-space defined by f, where high-dimensional matrix multiplication may be used. Therefore, when the tokenization configuration includes at least one projection matrix f, one or more sensing semantics o may each be projected onto the sub-space defined by a corresponding projection matrix based on high-dimensional matrix multiplication to obtain a sensing token c, which provides another way for tokenizing sensing semantics, and thus the query can be conducted more flexibly and reasonably as required.

In a possible implementation, each of the at least one sensing semantic is represented by a graph or topology, and the tokenization configuration includes at least one graph-based or topology-based pruning, and the tokenizing at least one sensing semantic to at least one sensing token based on the tokenization configuration includes: selecting a subgraph, or a partial topology, or partial parameters from the graph or topology represented by each of one or more sensing semantics based on an approach or criterion defined by a corresponding one of the at least one graph-based or topology-based pruning, to obtain a corresponding sensing token.

In details, the each of the at least one sensing semantic is represented by the graph or topology, and the tokenization configuration includes at least one graph-based or topology-based pruning f, which can be:

$$o {⟶}^{f} c ,$$

i.e., f defines the approaches or criterions on how to select subgraph, or partial topology, or partial parameters from the sensing semantic o, so as to achieve c. In order to do the pruning, the sensing semantic o may be represented by a graph or topology first. Therefore, when each of the at least one sensing semantic is represented by a graph or topology, the tokenization configuration may include at least one graph-based or topology-based pruning f, and tokenization may be performed by selecting a subgraph, or a partial topology, or partial parameters from the graph or topology represented by each of one or more sensing semantics o based on an approach or criterion defined by a corresponding graph-based or topology-based pruning, which can realize tokenization of sensing semantics o represented by a graph or topology and support query based on graph-represented or topology-represented semantics, and thus the query can be conducted more flexibly and reasonably as required.

In a possible implementation, the tokenization configuration includes at least one compression approach, and the tokenizing at least one sensing semantic to at least one sensing token based on the tokenization configuration includes: compressing, based on a corresponding one of at least one compression approach, each of one or more sensing semantics to obtain a corresponding sensing token, where the compression approach includes at least one of transformation, quantization, coefficients selection, or entropy coding.

In details, the tokenization configuration includes at least one compression approach f. For example, f includes 4 compression steps: step 1) is transformation, step 2) is quantization, step 3) is coefficients selection, and step 4) is entropy coding. After applying several compression steps on the sensing semantic o, the compressed information c will be achieved. Therefore, when the tokenization configuration includes at least one compression approach, a corresponding sensing token c may be obtained by compressing each of one or more sensing semantics o, based on a corresponding compression approach f, which can realize tokenization by compressing, and thus the query can be conducted more flexibly and reasonably according to actual demands.

S920, obtaining at least one query message.

In details, the first apparatus may obtain the at least one query message from the second apparatus.

S930, tokenizing at least one sensing semantic to at least one sensing token based on the tokenization configuration, where each of the at least one sensing semantic is tokenized to a corresponding sensing token.

In details, the first apparatus may tokenize the at least one sensing semantic to the at least one sensing token based on the tokenization configuration, where each of the at least one sensing semantic is tokenized to a corresponding sensing token. As described above, the first apparatus may obtain the tokenization configuration from the second apparatus in advance, so that the first apparatus can convert the sensing semantic to sensing token for further determining the relevance to the query message (where the first apparatus obtains its sensing semantic based on the sensing environment/sensed data). It is noted that, with the tokenization conversion, privacy may be protected, where both the task, goal, or query and sensed data may be well protected, and no raw data or minimum raw data or message is transmitted over the air.

S940, determining, from the at least one sensing token, one or more sensing tokens matching one or more query messages.

In details, once the first apparatus obtains a query message, the first apparatus may become waken but with little idea whether or not its sensed data is sufficiently relevant to the goal conveyed by the query message. Thereby the first apparatus may enable its sensing gadget to sense its nearby environment into sensed data and compare the sensed data with the query message. The comparison approach may be, for example, the comparison between the query token and the sensing token. In other words, the first apparatus may convert the sensing semantic to sensing token based on the tokenization configuration (where the first apparatus obtains its sensing semantic based on the sensing environment/sensed data), and then compare the sensing token with the query token so as to determine whether or not its sensed data is sufficiently relevant to the goal conveyed by the query token. Before being used for generating a sensing token, the tokenization configuration may be sent to the first apparatus from the second apparatus in advance, which means that before the tokenization configuration is used for converting a piece of sensed data to a sensing token, the first apparatus and the second apparatus have communicated with each other to configure the tokenization configuration. Moreover, the tokenization configuration may also be used for converting the query message to a query token if necessary. It is noted that when the first apparatus determines whether or not its sensed data is sufficiently relevant to the goal conveyed by the query message, other comparison approach may also be used, for example, the comparison between the query semantic and the sensing semantic, which is not limited herein.

S950, sending a sensing result, where the sensing result includes at least one piece of sensed data and/or at least one sensing semantic corresponding to the determined one or more sensing tokens.

In a possible implementation, the at least one piece of sensed data includes at least one piece of raw sensed data, half raw sensed data, or compressed sensed data.

In details, if the first apparatus tells that the sensed data is sufficiently relevant with the query message, the first apparatus encodes and sends the sensed data to the second apparatus. Further, the sensed data can be sent in many forms, such as, raw sensed data, half raw sensed data, compressed sensed data, or sensing semantic converted from the raw sensed data, which is not limited herein. In other words, if all of the at least one sensing token matches the query token, all the sensed data may be sent to the second apparatus in at least one form as described above, while if part of the at least one sensing token match the query token, only the matched sensed data may be sent to the second apparatus in at least one form.

In a possible implementation, each of the at least one query message corresponds to a task, a modality, or a combination of a task and a modality.

For example, the query message 1 may correspond to task 1 “find moving obstacles” and the query message 2 may correspond to task 2 “localize incoming pedestrians,” which is not limited herein. Because each query message may correspond to a task, a modality, or a combination of the task and the modality, the query may be conducted more flexibly and reasonably according to the task and/or modality.

In a possible implementation, each of the at least one query message includes at least one identifier, where the at least one identifier indicates a task identifier, a modality identifier, or both a task identifier and a modality identifier.

In a possible implementation, the obtaining a tokenization configuration includes: obtaining, for each of the at least one query message and based on the at least one identifier for the each of the at least one query message, at least one tokenization model matching the at least one identifier in the tokenization configuration, at least one function matching the at least one identifier in the tokenization configuration, at least one projection matrix matching the at least one identifier in the tokenization configuration, at least one graph-based or topology-based pruning matching the at least one identifier in the tokenization configuration, or at least one compression approach matching the at least one identifier in the tokenization configuration.

In details, the tokenization configuration (including several kinds of tokenization models, or the functions/approaches) is obtained by the first apparatus from the second apparatus, where the tokenization models, or the functions/approaches may correspond to their respective identifiers (for example, their task identifiers, modality identifiers, or both the task identifiers and the modality identifiers). Then once obtaining the query message(s) including the identifier(s) from the second apparatus, the first apparatus may directly obtain the tokenization model(s) or the function(s)/approach(s) based on the identifier(s) included in the query message(s) and the identifier(s) corresponding to the tokenization model(s), or the function(s)/approach(es). For example, the tokenization model 1 may correspond to task 1 “find moving obstacles” with task identifier t₁ and the tokenization model 2 may correspond to task 2 “localize incoming pedestrians” with task identifier t₂, and the query message 1 and query message 2 are obtained, where the query message 1 may correspond to task 2 “localize incoming pedestrians” and include task identifier t₂, while the query message 2 may correspond to task 1 “find moving obstacles” and include task identifier t₁, and then, since the query message 1 includes task identifier t₂, the tokenization model 2 corresponding to the task identifier t₂ can be obtained for the query message 1 to tokenize sensing semantics to sensing tokens for the query message 1, i.e., for task t₂, and similarly, the tokenization model 1 corresponding to the task identifier t₁ can be obtained for the query message 2 including the task identifier t₁ so as to tokenize sensing semantics to sensing tokens for the query message 2, i.e., for task t₁. In this way, a suitable tokenization model or function/approach can be obtained efficiently.

With the sensing communication method provided by the present disclosure, an apparatus such as a sensing device may obtain query message(s) and tokenization configuration from other apparatus such as a central device and respond with sensing result(s) in response to the obtained query message(s). The sensing result(s) may include at least one piece of sensed data and/or at least one sensing semantic corresponding to sensing token(s) that is determined from at least one sensing token and matches query message(s), where the at least one sensing token is tokenized from at least one sensing semantic based on the tokenization configuration. Thus, query may be conducted flexibly and reasonably based on the tokenization configuration, and the privacy would be protected.

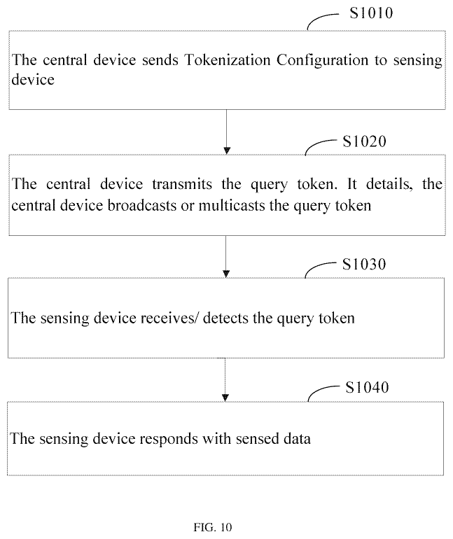

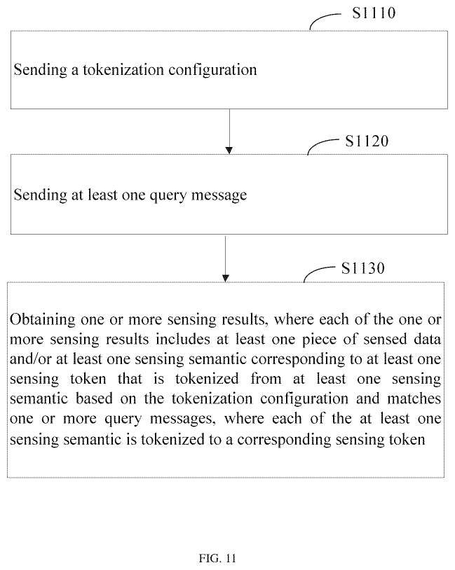

FIG. 10 is another schematic flowchart of a sensing communication method according to one or more example embodiments of the present disclosure.

In details, a sensing device may compare its sensed data with the query message; after the sensing device receives a query token, the sensing device is waked up to enable its sensing gadget to measure its nearby physical-word environment into a sensed data; the sensing device may be equipped with one LLM or LLMs as semantization model and input the sensed data into the semantization model to output a sensing semantic; and the sensing device may continue to tokenize the sensing semantic into a sensing token; the sensing device compares or scores the relevance between the query message and sensed data, which is based on what the sensing device has received; if the sensing device tells that the sensed data is sufficiently relevant with the query message, the sensing device encodes and transmits the sensed data to the central device; otherwise, the sensing may not respond to the query message at all.

The central device may configure the tokenization model, or the functions/approaches to the sensing device, which will be used by the sensing device to tokenize the sensing semantic into a sensing token. The procedure may include at least one of the following steps:

S1010: The central device sends Tokenization Configuration to sensing device.

In details, the central device broadcasts/multicasts/unicasts Tokenization Configuration to sensing device. The Tokenization Configuration message can be carried in SSB for broadcast, or in multicast configuration targeted to a group of sensing devices, or dedicated to one sensing device.

We use the abbreviation “f” to represent configured tokenization model, or the function/approach used for tokenization. Suppose the sensing semantic is “o,” and “f” will be used by the sensing device to tokenize the sensing semantic “o” into a sensing token “c.” “f” can have several representations:

Option 1: f can be a deep learning model, with sensing semantic o as input, and sensing token c as output.

Option 2: f can be a function: c=f(o), i.e., sensing token c will be obtained by applying function f with sensing semantic o as function parameters.

Option 3: f can be a projection matrix: c=fo, i.e., sensing token c will be obtained by projecting sensing semantic o onto a sub-space defined by f. High-dimensional matrix multiplication may be used.

Option 4: f can be a graph-based or topology-based pruning:

$$o {⟶}^{f} c ,$$

i.e., f defines the approaches or criterions on how to select subgraph, or partial topology, or partial parameters from the sensing semantic o, so as to achieve c. In order to do the pruning, the sensing semantic o may be represented by a graph or topology first.

Option 5: f can be some compression steps. For example, f includes 4 compression steps: step 1) is transformation, step 2) is quantization, step 3) is coefficients selection, and step 4) is entropy coding. After applying several compression steps on the sensing semantic o, the compressed information c will be achieved.

Note that f will maintain the distance in sensing semantic space and sensing token space. For example, suppose two sensing semantics are o1 and o2, f tokenizes o1 to c1, and tokenizes o2 to c2, respectively. If the distance between o1 and o2, represented as d (o1, o2), is small, it means that the distance between c1 and c2, d′ (c1, c2) is also small.

Optionally, when the central device configures the tokenization model, or the functions/approaches to the sensing device, the parameters for f can also be indicated.

If there are multiple tasks/modalities, multiple f will be configured, i.e., the central device will configure a set of tokenization models, or functions/approaches to the sensing device: {f₁, f₂, . . . , fₛ}, s≥1. s is the number of tokenization models, or the functions/approaches configured for tokenization, and different fi represents the tokenization model, or the function/approach for different tasks (or modalities), i∈[1, s].

S1020: The central device transmits the query token. It details, the central device broadcasts or multicasts the query token.

It can include one or more query tokens: {q₁, q₂, . . . qₙ}, where n is the number of query tokens.

Optionally, the identifier for the query can be included in the query message. For example, for query qᵢ, its identifier tᵢ can be included to indicate its task ID (or modality ID, or both task ID and modality ID).

S1030: The sensing device receives/detects the query token.

Based on the sensing environment/sensed data, sensing device obtains its sensing semantic o, and then tokenize the sensing semantic o to a sensing token c based on the configured tokenization model, or the function/approach used for tokenization in S1010. If the sensing device tells that the sensing token is close to, or matches the query, then sensing device will response with sensed data.

Optionally, if the identifier for the query token is included, e.g., if the identifier tᵢ for query token qi is included to indicate its task ID (or modality ID, or both task ID and modality ID), then sensing device may use the identifier tᵢ to obtain the previously configured tokenization model, or function/approach used for tokenization.

S1040: The sensing device responds with sensed data.

The sensed data from sensing device can include matched raw sensed data and/or sensing semantics in S1030.

With the sensing communication method provided by the present disclosure, an apparatus such as a sensing device may obtain query message(s) and tokenization configuration from other apparatus such as a central device and respond with sensing result(s) in response to the obtained query message(s). The sensing result(s) may include at least one piece of sensed data and/or the at least one sensing semantic corresponding to one or more sensing tokens that is determined from at least one sensing token and matches one or more query messages, where the at least one sensing token is tokenized from at least one sensing semantic based on the tokenization configuration including several kinds of tokenization models, or the functions/approaches as required. Thus, query may be conducted flexibly and reasonably based on the based on the tokenization configuration, and the privacy would be protected.

In the above, the sensing communication method of the present disclosure is described from the perspective of the first apparatus (such as the sensing device) in combination with FIG. 9 and FIG. 10. In the following, a sensing communication method of the present disclosure will be described from the perspective of the second apparatus (such as the central device) in combination with FIG. 11.

FIG. 11 is another schematic flowchart of a sensing communication method according to one or more example embodiments of the present disclosure. The method can be implemented by a second apparatus. Optionally, the second apparatus can be a central device or other device that has similar function (for example, the second apparatus could be a chip), which is not limited herein. As shown in FIG. 11, the method can include the following steps.

S1110, sending a tokenization configuration.

In details, a second apparatus may send the tokenization configuration to the first apparatus in advance so that the first apparatus can token sensing semantic and/or a query message based on the tokenization configuration that is known from both sides of the second apparatus and the first apparatus (where the first apparatus obtains its sensing semantic based on the sensing environment/sensed data). Optionally, the second apparatus can be a central device or other device that has similar function (for example, the second apparatus could be a chip), which is not limited herein.

In a possible implementation, the tokenization configuration may be sent via a broadcast message, via a multicast message targeted to a group of apparatuses including the first apparatus; or via a dedicated message to the first apparatus.

In details, the second apparatus may send the tokenization configuration in different ways. For example, by means of broadcasting or multicasting, a large number of apparatuses may be scheduled rather than one-to-one individual scheduling, the resource consumption can be reduced. By means of unicasting, one-to-one individual scheduling can be achieved for special query dedicated to a specific apparatus.

In a possible implementation, the tokenization configuration may include at least one of: at least one tokenization model; at least one function; at least one projection matrix; at least one graph-based or topology-based pruning; or at least one compression approach.

In details, tokenization may be implemented by using various tokenization models, or functions/approaches for tokenization, where approaches for tokenization may include but not limited to a projection matrix, a graph-based or topology-based pruning, and a compression approach. For example, the tokenization configuration may include one or more tokenization models, or the tokenization configuration may include one or more projection matrixes, or the tokenization configuration may include one or more tokenization models and one or more compression approaches, which is not limited herein. The tokenization configuration may be determined according to actual needs. For example, if there is simple type of query message, the tokenization configuration may include one of at least one tokenization model; at least one function; at least one projection matrix; at least one graph-based or topology-based pruning; or at least one compression approach. Alternatively, if there are multiple complicated types of query messages, the tokenization configuration may include multiple of at least one tokenization model; at least one function; at least one projection matrix; at least one graph-based or topology-based pruning; or at least one compression approach. Whether the tokenization configuration includes one or multiple tokenization manners depends on the specific condition, which is not limited herein. Thus, flexibility and reasonability of query may be further improved based on the tokenization configuration of several kinds of tokenization models, or the functions/approaches as required.

In a possible implementation, at least one of a set of tokenization models, a set of functions, a set of projection matrixes, a set of graph-based or topology-based pruning, or a set of compression approaches are configured for multiple tasks, for multiple modalities, or for multiple combinations of task and modality.

A set of tokenization models, a set of functions, a set of projection matrixes, a set of graph-based or topology-based pruning, and/or a set of compression approaches may be configured for multiple tasks and/or multiple modalities. Taking the tokenization model as an example, tokenization model 1 may correspond to task 1 “find moving obstacles” and tokenization model 2 may correspond to task 2 “localize incoming pedestrians,” which is not limited herein. In this way, query may be conducted more flexibly and reasonably by using various tokenization models, functions, projection matrixes, graph-based or topology-based pruning and/or compression approaches according to tasks and/or modalities.

In a possible implementation, each tokenization model of the set of tokenization models, each function of the set of functions, each projection matrix of the set of projection matrix, each graph-based or topology-based pruning of the set of graph-based or topology-based pruning, or each compression approach of the set of compression approaches corresponds to at least one identifier indicating a task identifier, a modality identifier, or both a task identifier and a modality identifier.

Because each one in the set of tokenization models, the set of functions, the set of projection matrix, the set of graph-based or topology-based pruning, or the set of compression approaches may correspond to at least one identifier, the first apparatus can determine a specific tokenization model or function/approach for a task with a task identifier, or for a modality with a modality identifier, or for a combination of a task and a modality with task and modality identifiers when generating the sensing token. Taking the tokenization model as an example, the tokenization model 1 may correspond to task 1 “find moving obstacles” with task identifier t₁ and the tokenization model 2 may correspond to task 2 “localize incoming pedestrians” with task identifier t₂, which is not limited herein. This flexibility and reasonability of query may be further improved based on the at least one identifier.

As discussed above, the second apparatus may broadcasts/multicasts/unicasts the tokenization configuration to the first apparatus. It is supposed that the abbreviation “f” may be used to represent configured tokenization model, or the function/approach used for tokenization, the abbreviation “o” may be used to represent the sensing semantic, and the abbreviation “c” may be used to represent the sensing token. Therefore the configured tokenization model, or the function/approach f may be used by the first apparatus to tokenize the sensing semantic o into the sensing token c, where the configured tokenization model, or the function/approach f may have several representations, which is discussed below.

In a possible implementation, the tokenization configuration includes at least one tokenization model, and each of one or more sensing tokens is tokenized from a corresponding sensing semantic based on a corresponding one of the at least one tokenization model. Optionally, each of the at least one tokenization model is a deep learning model, and each of one or more sensing tokens is tokenized from a corresponding sensing semantic by inputting the corresponding sensing semantic into corresponding one of at least one deep learning model to obtain the each of the at least one sensing token.

In details, the tokenization configuration may include at least one tokenization model f, which can be a deep learning model, with sensing semantic o as input, and sensing token c as output. Therefore, when adopting a deep learning model as the tokenization model f, the corresponding sensing token c may be obtained by inputting each of one or more sensing semantics o into a corresponding deep learning model f, and thus the query can be conducted more flexibly and reasonably as required based on the deep learning model.

In a possible implementation, the tokenization configuration includes at least one function, and each of one or more sensing tokens is tokenized from a corresponding sensing semantic by applying a corresponding one of at least one function with the corresponding sensing semantic as a function parameter to obtain the each of the at least one sensing token.

In details, the tokenization configuration includes at least one function f, which can be c=f(o), i.e., sensing token c will be obtained by applying function f with sensing semantic o as function parameters. Therefore, when the tokenization configuration includes at least one function, a corresponding function may be applied with each of one or more sensing semantics o as a function parameter, thereby obtaining a sensing token c based on a function f, which may be simpler and need less computation resources than some other forms of tokenization configurations, and thus the query can be conducted more flexibly and reasonably as required.

In a possible implementation, the tokenization configuration includes at least one projection matrix, and each of one or more sensing tokens is tokenized from a corresponding sensing semantic by projecting the corresponding sensing semantic onto a sub-space defined by a corresponding one of the at least one projection matrix based on a high-dimensional matrix multiplication to obtain the each of the at least one sensing token.

In details, the tokenization configuration includes the at least one projection matrix f, which can be c=fo, i.e., sensing token c will be obtained by projecting sensing semantic o onto a sub-space defined by f, where high-dimensional matrix multiplication may be used. Therefore, when the tokenization configuration includes at least one projection matrix f, one or more sensing semantics o may each be projected onto the sub-space defined by a corresponding projection matrix based on high-dimensional matrix multiplication to obtain a sensing token c, which provides another way for tokenizing sensing semantics, and thus the query can be conducted more flexibly and reasonably as required.

In a possible implementation, each of the at least one sensing semantic is represented by a graph or topology, and the tokenization configuration includes at least one graph-based or topology-based pruning, and each of one or more sensing tokens is tokenized from a corresponding sensing semantic by selecting a subgraph, or a partial topology, or partial parameters from the graph or topology represented by each of the at least one sensing semantic based on an approach or criterion defined by a corresponding one of the at least one graph-based or topology-based pruning, to obtain the each of the at least one sensing token.

In details, the each of the at least one sensing semantic is represented by the graph or topology, and the tokenization configuration includes at least one graph-based or topology-based pruning f, which can be:

$$o {⟶}^{f} c ,$$

i.e., f defines the approaches or criterions on how to select subgraph, or partial topology, or partial parameters from the sensing semantic o, so as to achieve c. In order to do the pruning, the sensing semantic o may be represented by a graph or topology first. Therefore, when each of the at least one sensing semantic is represented by a graph or topology, the tokenization configuration may include at least one graph-based or topology-based pruning f, and tokenization may be performed by selecting a subgraph, or a partial topology, or partial parameters from the graph or topology represented by each of one or more sensing semantics o based on an approach or criterion defined by a corresponding graph-based or topology-based pruning, which can realize tokenization of sensing semantics o represented by a graph or topology and support query based on graph-represented or topology-represented semantics, and thus the query can be conducted more flexibly and reasonably as required.

In a possible implementation, the tokenization configuration includes at least one compression approach, and each of one or more sensing tokens is tokenized from a corresponding sensing semantic by compressing, using a corresponding one of the at least one compression approach, the corresponding sensing semantic to obtain the each of the at least one sensing token, where the compression approach includes at least one of transformation, quantization, coefficients selection, or entropy coding.

In details, the tokenization configuration includes at least one compression approach f. For example, f includes 4 compression steps: step 1) is transformation, step 2) is quantization, step 3) is coefficients selection, and step 4) is entropy coding. After applying several compression steps on the sensing semantic o, the compressed information c will be achieved. Therefore, when the tokenization configuration includes at least one compression approach, a corresponding sensing token c may be obtained by compressing each of one or more sensing semantics o, based on a corresponding compression approach f, which can realize tokenization by compressing, and thus the query can be conducted more flexibly and reasonably according to actual demands.

S1120, sending at least one query message.

In details, the second apparatus may send the at least one query message to the first apparatus.

S1130, obtaining one or more sensing results, where each of the one or more sensing results includes at least one piece of sensed data and/or at least one sensing semantic corresponding to at least one sensing token that is tokenized from at least one sensing semantic based on the tokenization configuration and matches one or more query messages, where each of the at least one sensing semantic is tokenized to a corresponding sensing token.

In details, the first apparatus may tokenize the at least one sensing semantic to the at least one sensing token based on the tokenization configuration, where each of the at least one sensing semantic is tokenized to a corresponding sensing token. As described above, the first apparatus may obtain the tokenization configuration from the second apparatus in advance, so that the first apparatus can convert the sensing semantic to sensing token for further determining the relevance to the query message (where the first apparatus obtains its sensing semantic based on the sensing environment/sensed data). It is noted that, with the tokenization conversion, privacy may be protected, where both the task, goal, or query and sensed data may be well protected, and no raw data or minimum raw data or message is transmitted over the air.

More specifically, once the first apparatus obtains a query message, the first apparatus may become waken but with little idea whether or not its sensed data is sufficiently relevant to the goal conveyed by the query message. Thereby the first apparatus may enable its sensing gadget to sense its nearby environment into sensed data and compare the sensed data with the query message. The comparison approach may be, for example, the comparison between the query token and the sensing token. In other words, the first apparatus may convert the sensing semantic to sensing token based on the tokenization configuration (where the first apparatus obtains its sensing semantic based on the sensing environment/sensed data), and then compare the sensing token with the query token so as to determine whether or not its sensed data is sufficiently relevant to the goal conveyed by the query token. Before being used for generating a sensing token, the tokenization configuration may be sent to the first apparatus from the second apparatus in advance, which means that before the tokenization configuration is used for converting a piece of sensed data to a sensing token, the second apparatus and the first apparatus have communicated with each other to configure the tokenization configuration. Moreover, the tokenization configuration may also be used for converting the query message to a query token if necessary. It is noted that when the first apparatus determines whether or not its sensed data is sufficiently relevant to the goal conveyed by the query message, other comparison approach may also be used, for example, the comparison between the query semantic and the sensing semantic, which is not limited herein.

If the first apparatus tells that the sensed data is sufficiently relevant with the query message, the first apparatus encodes and sends the sensed data to the second apparatus for obtaining. In a possible implementation, the at least one piece of sensed data includes at least one piece of raw sensed data, half raw sensed data, or compressed sensed data. In other words, the sensed data can be obtained in many forms, such as, raw sensed data, half raw sensed data, compressed sensed data, or sensing semantic converted from the raw sensed data, which is not limited herein. In other words, if all of the at least one sensing token matches the query token, all the sensed data may be obtained by the second apparatus in at least one form as described above, while if part of the at least one sensing token match the query token, only the matched sensed data may be obtained by the second apparatus in at least one form.

In a possible implementation, each of the at least one query message corresponds to a task, a modality, or a combination of a task and a modality.

For example, the query message 1 may correspond to task 1 “find moving obstacles” and the query message 2 may correspond to task 2 “localize incoming pedestrians,” which is not limited herein. Because each query message may correspond to a task, a modality, or a combination of the task and the modality, the query may be conducted more flexibly and reasonably according to the task and/or modality.

In a possible implementation, each of the at least one query message includes at least one identifier, where the at least one identifier indicates a task identifier, a modality identifier, or both a task identifier and a modality identifier.

In a possible implementation, the at least one identifier for the each of the at least one query message is used for a first apparatus to obtaining, for each of the at least one query message, at least one tokenization model matching the at least one identifier in the tokenization configuration, at least one function matching the at least one identifier in the tokenization configuration, at least one projection matrix matching the at least one identifier in the tokenization configuration, at least one graph-based or topology-based pruning matching the at least one identifier in the tokenization configuration, or at least one compression approach matching the at least one identifier in the tokenization configuration.

In details, the tokenization configuration (including several kinds of tokenization models, or the functions/approaches) is obtained by the first apparatus from the second apparatus, where the tokenization models, or the functions/approaches may correspond to their respective identifiers (for example, their task identifiers, modality identifiers, or both the task identifiers and the modality identifiers). Then once obtaining the query message(s) including the identifier(s) from the second apparatus, the first apparatus may directly obtain the tokenization model(s) or the function(s)/approach(s) based on the identifier(s) included in the query message(s) and the identifier(s) corresponding to the tokenization model(s), or the function(s)/approach(es). For example, the tokenization model 1 may correspond to task 1 “find moving obstacles” with task identifier t₁ and the tokenization model 2 may correspond to task 2 “localize incoming pedestrians” with task identifier t₂, and the query message 1 and query message 2 are obtained, where the query message 1 may correspond to task 2 “localize incoming pedestrians” and include task identifier t₂, while the query message 2 may correspond to task 1 “find moving obstacles” and include task identifier t₁, and then, since the query message 1 includes task identifier t₂, the tokenization model 2 corresponding to the task identifier t₂ can be obtained for the query message 1 to tokenize sensing semantics to sensing tokens for the query message 1, i.e., for task t₂, and similarly, the tokenization model 1 corresponding to the task identifier t₁ can be obtained for the query message 2 including the task identifier t₁ so as to tokenize sensing semantics to sensing tokens for the query message 2, i.e., for task t₁. In this way, a suitable tokenization model or function/approach can be obtained efficiently.

With the sensing communication method provided by the present disclosure, an apparatus such as a central device can send tokenization configuration and broadcast or multi-cast or unicast query message(s), so that other apparatus(es) such as one or more sensing devices can obtain the query message(s) and respond with sensing result(s) in response to the obtained query message(s). The sensing result(s) may include at least one piece of sensed data and/or at least one sensing semantic corresponding to sensing token(s) that is determined from at least one sensing token and matches query message(s), where the at least one sensing token is tokenized from at least one sensing semantic based on the tokenization configuration. Thus, query may be conducted flexibly and reasonably based on the tokenization configuration, and the privacy would be protected.

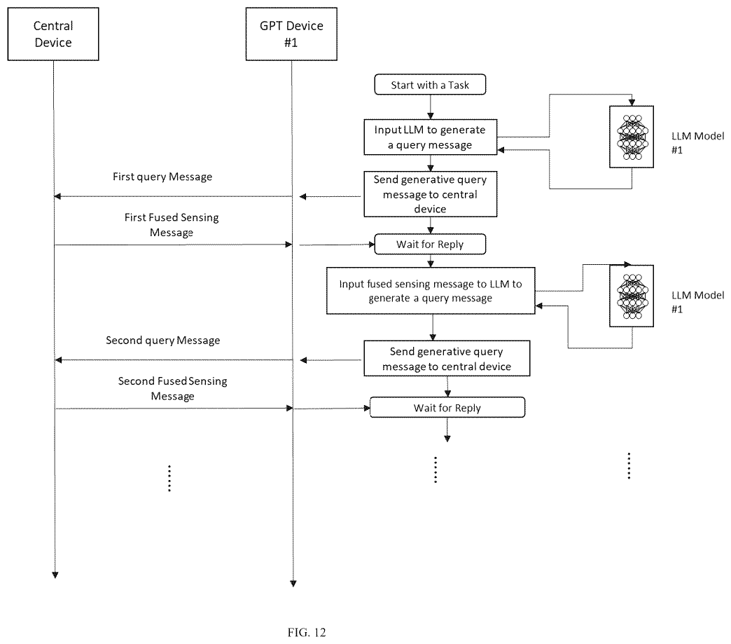

FIG. 12 is a schematic illustration of realizing a chain of thoughts according to one or more example embodiments of the present disclosure, where a chain of thoughts is realized by generative AI model and is embodied by a sequence of query messages.

A GPT device may generate a sequence of the query messages based on the previous sensing messages, wherein the previous sensing messages are received and/or fused by the central device. The GPT device may inference one or several generative AI models. The generative AI model or model inferences deep neural network or networks to output a query message or messages. The GPT device generates a sequence of the query messages, called as “a chain of the thoughts” by interacting with a sequence of the fused sensing messages into which the central device fuses the sensed data transmitted by the responsive sensing devices; as illustrated in FIG. 12.

A query message that the GPT device generate may convey semantic goals, tasks, or objectives. For example, a query message of “localize an incoming pedestrians” explicitly establishes a semantic goal for the sensing devices to focus on its nearby pedestrian and to prevent the sensing devices from being distracted. Since a query message conveys a semantic goal or goals, the query message that the central device transmits to the sensing devices may trigger a goal-oriented sensing task at each responsive sensing device that receives and responds to the very query message. Please note that a message may convey several goals. For example, a message of “find a moving pedestrian with white coat” conveys two semantic goals or tasks: a moving pedestrian and a pedestrian with white coat.

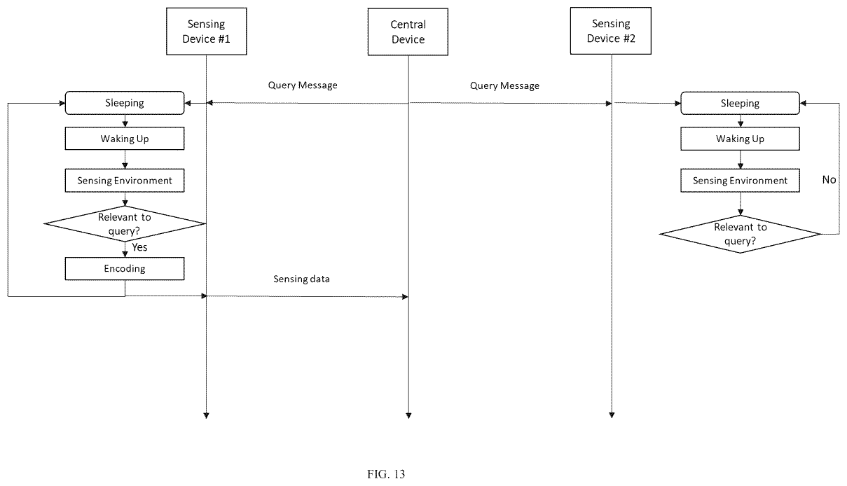

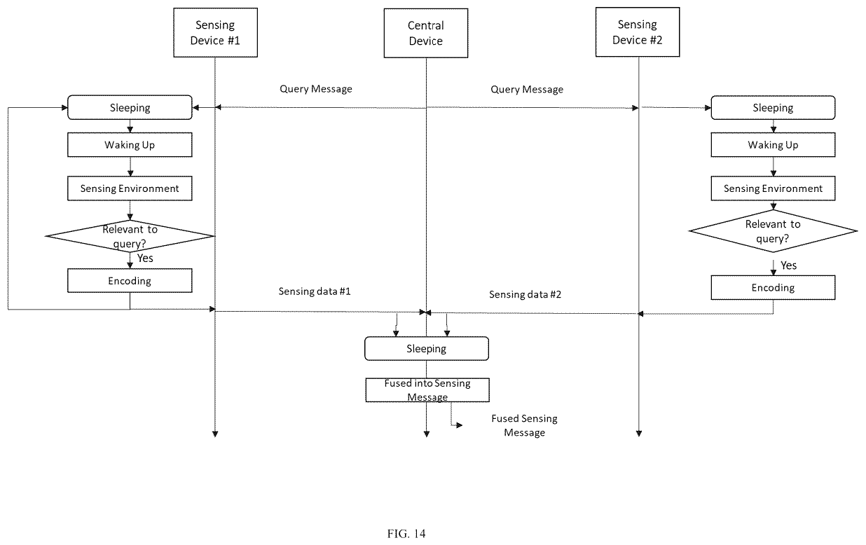

FIG. 13 is another schematic illustration of interaction among devices in a sensing communication scenario according to one or more example embodiments of the present disclosure. In the example, the sensing device #1 responds to the query message and the sensing device #2 doesn't respond to the query message.

In a possible implementation, as shown in FIG. 13, the central device may broadcast a sequence of the query messages, because it may be too costly or even forbidden to schedule sensing device individually in a wireless system including such a high density of sensing devices. Therefore, once a sensing device receives a query message, the sensing device may become waken but with little idea whether or not its sensed data is sufficiently relevant to the goal conveyed by the query message. Thereby the sensing device may enable its sensing gadget to sense its nearby environment into a sensed data and compare the sensed data with the query message. If the sensing device tells that the sensed data is sufficiently relevant with the query message, the sensing device encodes and transmits the sensed data to the central device (Sensing Device #1 in FIG. 13). Otherwise, the sensing may not respond to the query message at all (Sensing Device #2 in FIG. 13). In this sense, the wireless system does not schedule individual sensing devices but schedules a common task across a collectivity of sensing devices.

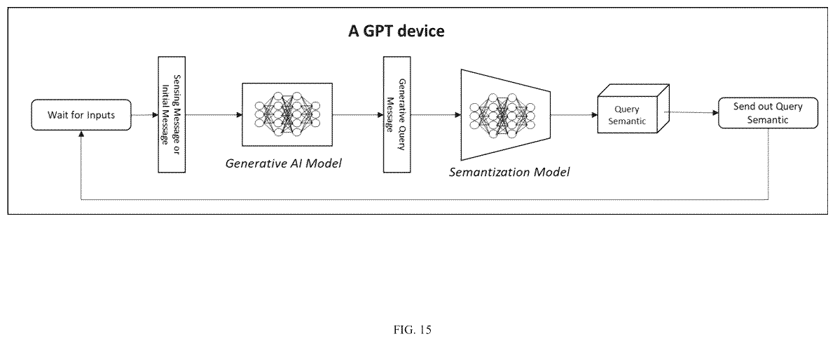

FIG. 14 is another schematic illustration of interaction among devices in a sensing communication scenario according to one or more example embodiments of the present disclosure. In the example, the central device receives the two sensed data from the two responsive sensing devices and fuse the two sensed data into a fused sensing message for the GPT device.

In a possible implementation, as shown in FIG. 14, the central device may receive a plurality of sensed data from some or all the sensing devices that respond to the query message at the end of a pre-defined responding timing interval. The central device may fuse all the sensed data into one sensing message and input the sensing message to the GPT device that would generate the next query message based on the sensing message, as shown in FIG. 14. Because only those sensing devices that respond to the query message would transmit the sensed data, lots of radio resources would be saved in comparison with one-to-one scheduling algorithm.

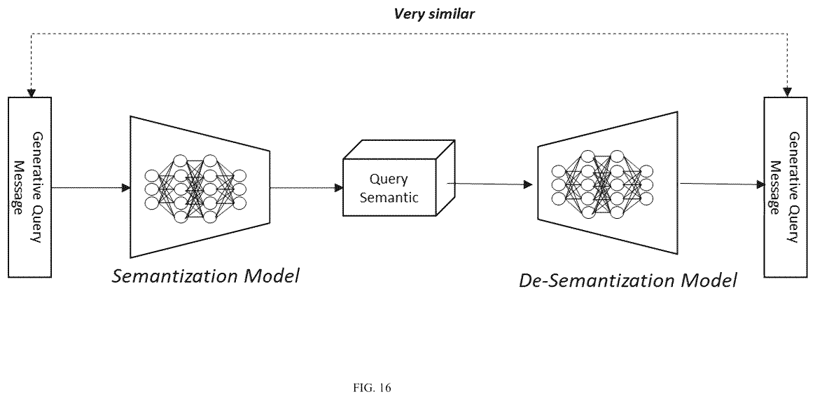

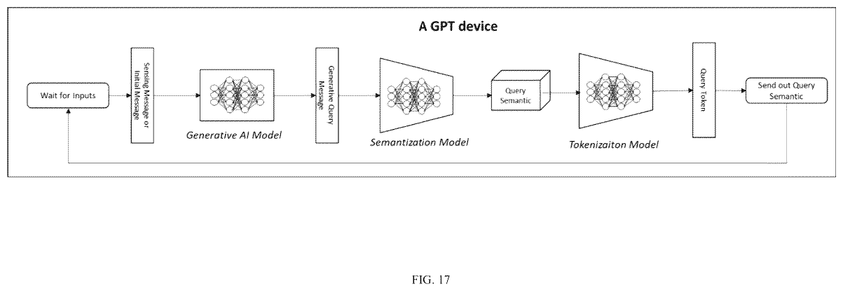

FIG. 15 is a schematic illustration of generating a query message, where GPT device uses generative AI model to generate the query message and then uses semantization model to translate the query message into a query semantic. FIG. 16 is a schematic illustration of reversing a semantic, where semantic is reversible, meaning that if someone had a de-semantization model, he could recover a query message from a query semantic.

A sequence of the query messages that the GPT device generates and the central device broadcasts is in a natural language, that is, human-readable. The GPT device may employ an LLM (large-language-model) to inference over a fused sensing message (in a natural language too) input to generate a new query message. The LLM model may be a “standard” foundation model like a transformer, or a “custom” model that is built for a narrower vocabulary and specific scenarios. For example, a customized LLM for dealing with industry 4.0 or a customized LLM for dealing with wireless communication signaling and protocols. The GPT device may change, update, downsize, upsize, replace its LLM or LLMs anytime as it wishes. Please note that broadcast, multicast or unicast is allowed.

A query message that the GPT device generates is in a natural language. Because of randomness in generating, two different query messages may convey a very similar semantic goal or goals. For example, “find a pedestrian” and “localize a walking man” may have the same semantic goal. Therefore, the GPT device may semantize a query message into a query semantic, which is called as “embedding,” “semantization,” “encoding,” “natural-language to machine translation” and so on. The GPT device may translate a query message into a query semantic that may include a vector, a matrix, or a tensor of scalars. The translation may be realized by deep-neural network or other classic functions. A query semantic may preserve all the key semantic goals conveyed by the query message such that the query semantic can be well translated (de-semantized) back to a query message. Optionally, the GPT device may transmit a query semantic instead of a query message to the central device, as illustrated in FIG. 15. Please note that if all the LLMs outputs to a common natural language (e.g., English), these LLMs are said to be aligned by the natural language; then whatever LLMs are used, everyone can be smoothly hooked into the GPT device and work well within the wireless system.

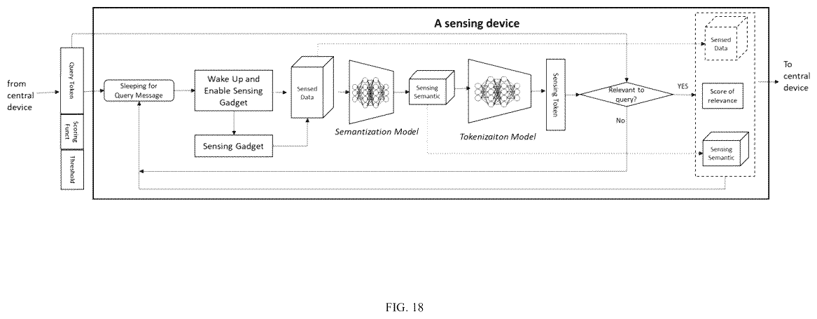

FIG. 17 is a schematic illustration of tokenizing a query semantic into a query token, where a GPT device tokenizes a query semantic into a query token.

In one implementation, the central device may further tokenize a query semantic into a query token. A query token is a fixed-length semantic but includes a vector of scalars, simpler for transmission and comparison purposes. The wireless system may pre-specify a plurality of lengths for query tokens. Thus, the central device may choose a right token length when tokenizing a query semantic according to the size range of the query semantic. The tokenization can be such a harsh function to prevent a sensing device from recovering a complete query message from a query token. The tokenization may come up with certain privacy protection for query messages. The tokenization may be realized by deep-neural network or other classic functions; as shown in FIG. 17.

Optionally, the central device receives a query semantic from the GPT device, and then the central device converts the query semantic into a query token with a fixed length; the central device may broadcast the query token with the length to all the sensing devices; the central device may keep the query semantic in its memory or storage to check the feedback sensed data.

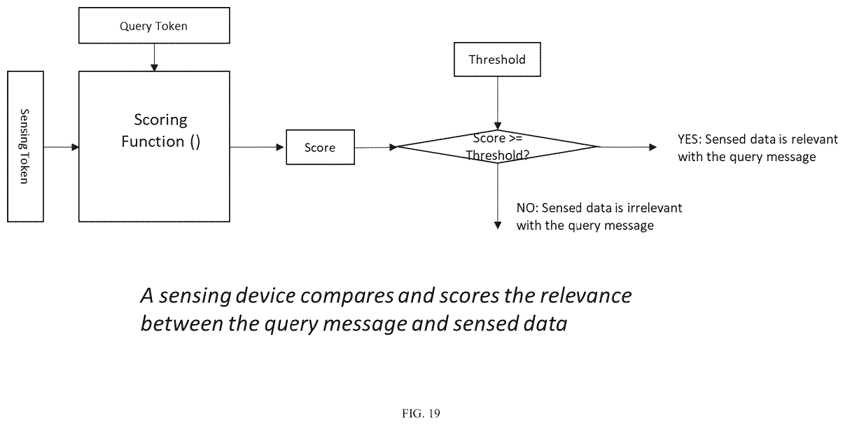

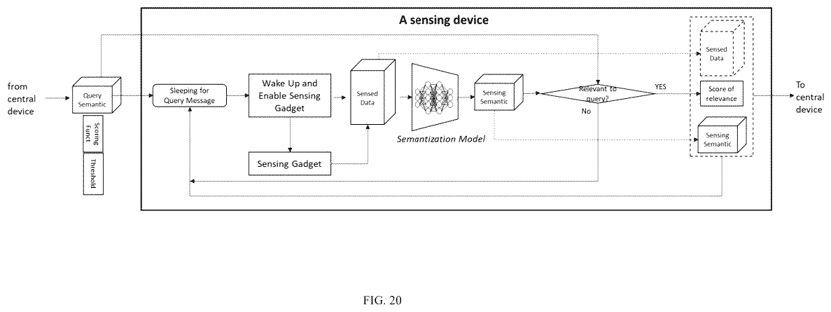

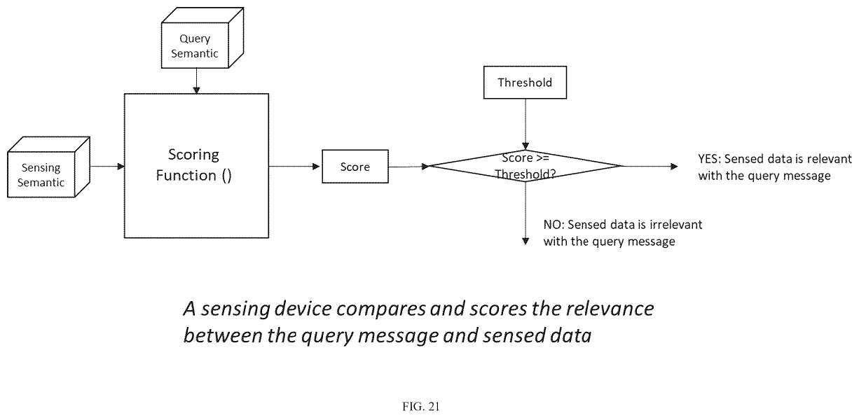

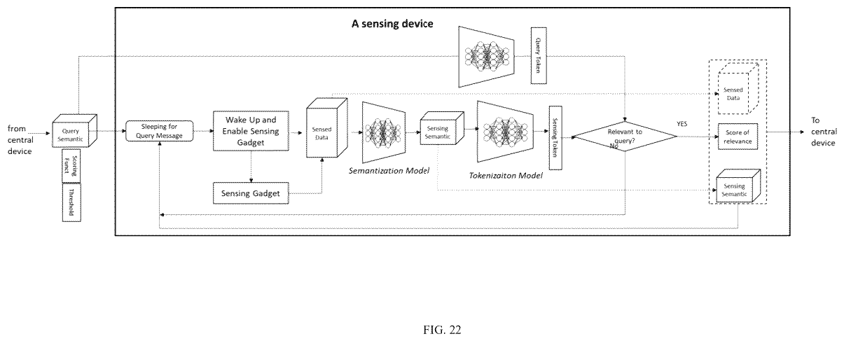

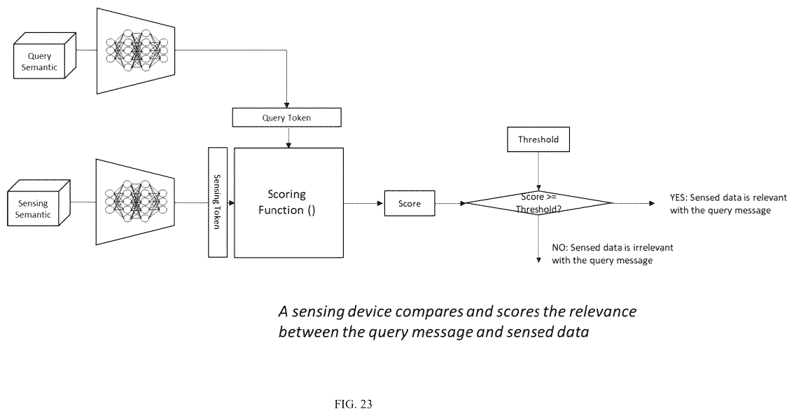

FIG. 18 is a schematic illustration of responding to a query token, where a sensing device responds to a query token. FIG. 19 is a schematic illustration of scoring the relevance with tokens, where score the relevance with tokens. FIG. 20 is another schematic illustration of responding to a query token, where a sensing device responds to a query token. FIG. 21 is a schematic illustration of scoring a relevance with semantic, where score the relevance with semantic. FIG. 22 is another schematic illustration of responding to a query token, where a sensing device responds to a query token. FIG. 23 is a schematic illustration of scoring the relevance with tokens converted from semantics, where score the relevance with tokens converted from semantics.

A sensing device may compare its sensed data with the query message; after the sensing device receives a query token (with its length or indicator of its length), the sensing device is waked up to enable its sensing gadget to measure its nearby physical-word environment into a sensed data; the sensing device may be equipped with one LLM or LLMs as semantization model and input the sensed data into the semantization model to output a sensing semantic; optionally, the sensing device may choose a right length and format of the sensing semantic; and the sensing device may continue to tokenize the sensing semantic into a sensing token with the same length as the query token that the sensing device has received; the sensing device compares or scores the relevance between the query message and sensed data, which is based on what the sensing device has received.

Alternative #1 (FIG. 18 and FIG. 19): the sensing device receives a query token and scoring function; it compares and scores the relevance between the query token and the sensing token; if the score of relevance was greater than or equal to a pre-defined threshold, the sensing device would tell that the sensed data is sufficiently relevant with the query message from the central device.

Alternative #2 (FIG. 20 and FIG. 21): the sensing device receives a query semantic and scoring function; it compares and scores the relevance between the query semantic with the sensing semantic, if both semantics are in a similar size and format; if the score of relevance was greater than or equal to a pre-defined threshold, the sensing device would tell that the sensed data is sufficiently relevant with the query message from the central device.

Alternative #3 (FIG. 22 and FIG. 23): the sensing device receives a query semantic and scoring function; it firstly converts the query semantic into a query token by the local tokenization model; and it compares and scores the relevance between the query token and sensing token; if the score of relevance was greater than or equal to a pre-defined threshold, the sensing device would tell that the sensed data is sufficiently relevant with the query message from the central device.

If the score of relevance is greater than or equal to a pre-defined threshold, the sensing device may transmit information including the sensed data and optionally the score of relevance to the central device. The following are some alternatives of the contents in the transmitted information:

```
  Alternative #1: raw sensed data;
  Alternative #2: sensing semantic;
  Alternative #3: half raw sensed data (e.g., exact value or number) +
  sensing semantic;
  Alternative #4: raw sensed data + score of relevance;
  Alternative #5: sensing semantic + score of relevance;
  Alternative #6: half raw sensed data (e.g., exact value or number) +
sensing semantic + score of relevance.
```

A sensing device may be equipped with one or several semantization models to generate sensing semantic from sensed (raw) data, may be equipped with tokenization model to generate sensing token from sensing semantic, and may be configured to have a scoring function; unlike the GPT device, the LLMs, tokenization model, and scoring functions that a sensing device may use are configured by the central device; the central device may configure and inform the sensing devices of a common LLMs and/or tokenization model and scoring function at all the beginning or on the run.

A plurality of sensing devices, either in one type or in multiple types, may serve one or several tasks simultaneously; in an efficient way, a sensing device may be triggered once to serve as many tasks as possible.

A wireless system may include two GPT devices, or one GPT device that can conduct two separate tasks; in the following disclosure, two GPT devices is mentioned as an example. And the two GPT devices may be easily extended to one GPT device with two separate tasks.

Although the two GPT devices have their own separate and independent tasks, the two GPT devices may trigger the same sensing devices simultaneously; for example, a driverless car GPT device and a traffic-light GPT device may trigger the same roadside camera sensing devices; nevertheless, although the same sensing devices may be triggered by two GPT devices at the same time interval, the query message from the first GPT device may be different from the query message from the second GPT device; for example, the driverless car GPT device may broadcast a query message about “moving obstacles” and the traffic-light GPT device may broadcast a query message about “density of vehicles,” both of which may be somehow relevant but not similar.

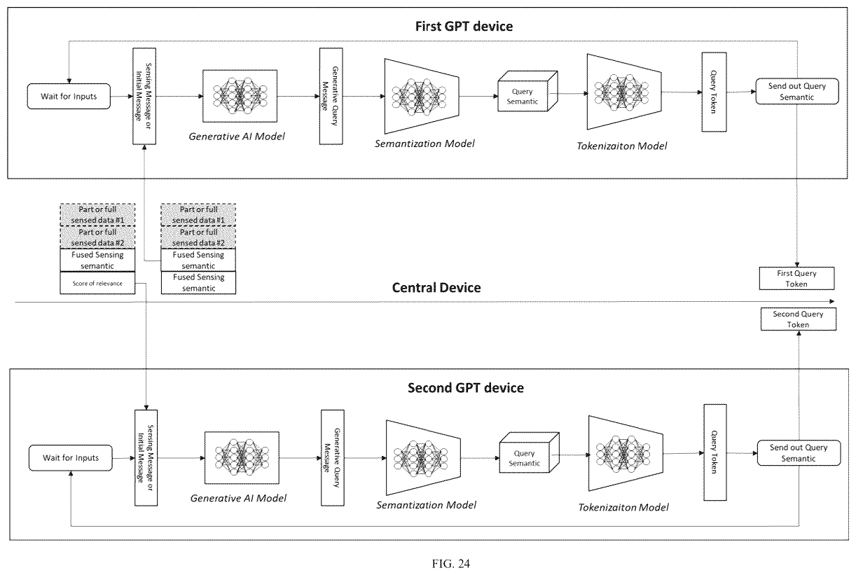

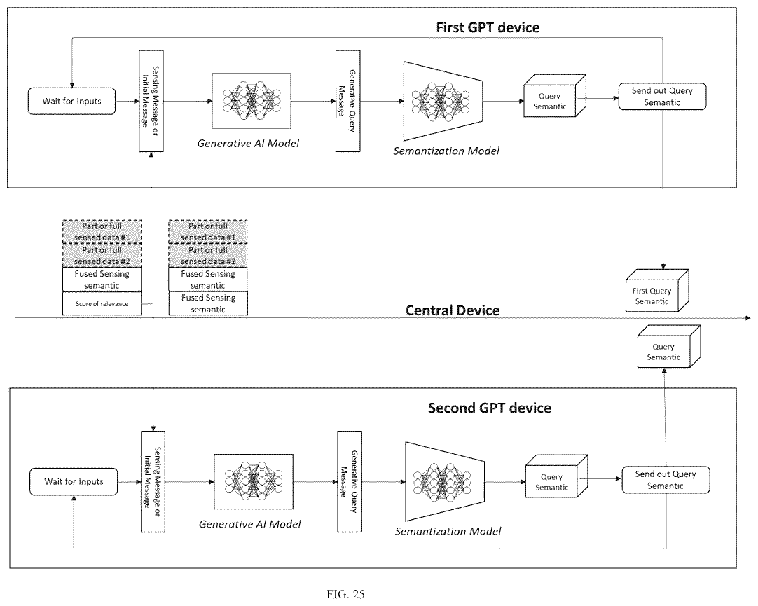

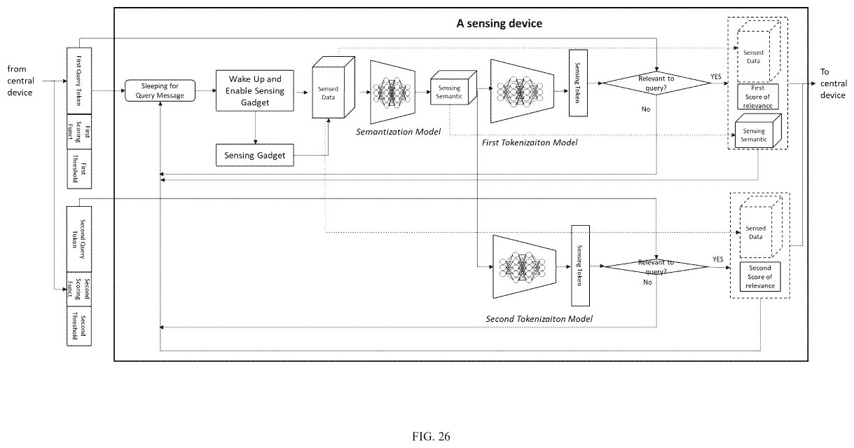

FIG. 24 is a schematic illustration of generating query tokens, where GPT devices generate the query tokens. FIG. 25 is a schematic illustration of generating query semantics, where GPT devices generate the query semantics.

The first GPT device generates the first query semantic to the central device and the second GPT device generates the second query semantic to the central device. There are two options shown as follows:

Alternative #1: as shown in FIG. 24, the central device may tokenize the first query message into the first query token and tokenize the second query message into the second query token; the central device may use the first tokenization model to tokenize the first query message and the second tokenization model to tokenize the second query message, or the central device may use a common tokenization model to tokenize the first query message and the second query message; then the central device may broadcast the first query token, the length of the first token, the first scoring function related to the first token, and the first threshold related to the first scoring function, and the second query token the length of the second token, the second scoring function related to the second token, and the second threshold related to the second scoring function in a multiplex way in DL channel(s);

Alternative #2: as shown in FIG. 25, the central device may not perform the tokenization, and the central device may broadcast the first query semantic, the length and format of the first semantic, the first scoring function related to the first semantic, and the first threshold related to the first scoring function, and the second query message the length of the second message, the second scoring function related to the second message, and the second threshold related to the second scoring function in a multiplex way in DL channel(s).

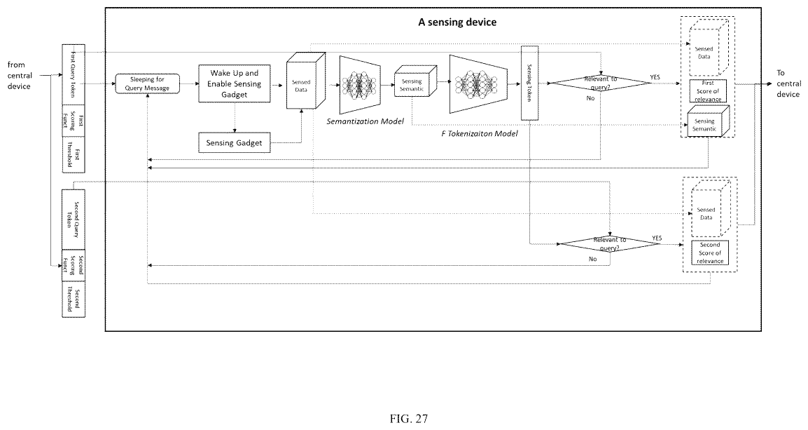

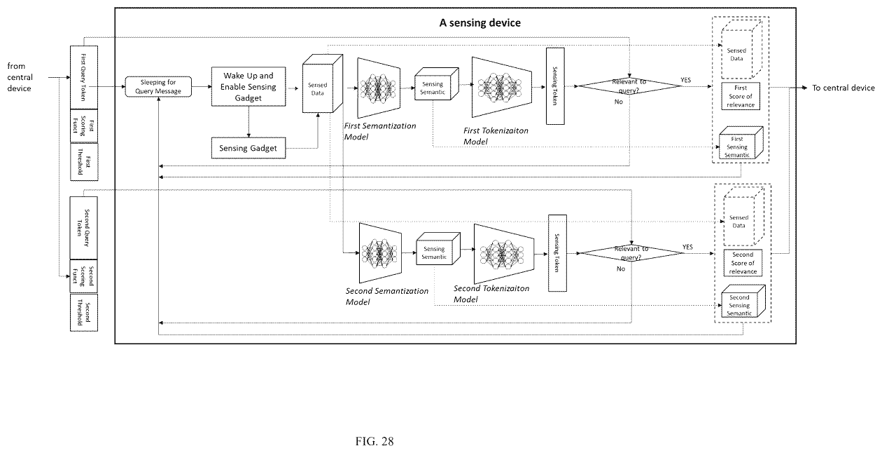

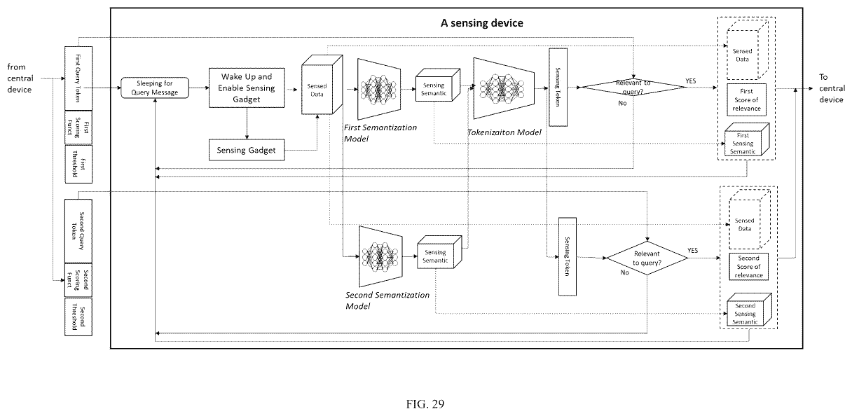

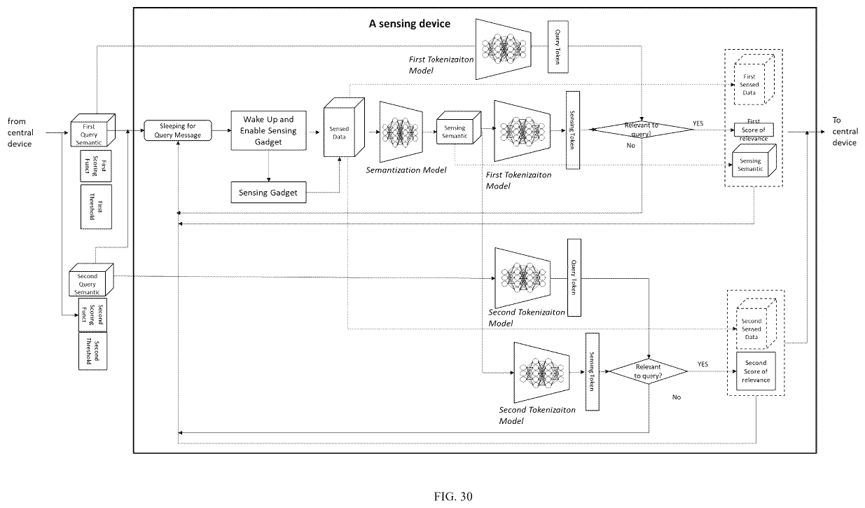

FIG. 26 is a schematic illustration of responding to two queries with a common semantization model and two tokenization models, where a sensing device responds to two queries with a common semantization model and two tokenization models. FIG. 27 is a schematic illustration of responding to two queries with a common semantization model and a common tokenization model, where a sensing device responds to two queries with a common semantization model and a common tokenization model. FIG. 28 is another schematic illustration of responding to two queries with two semantization models and two tokenization models, where a sensing device responds to two queries with two semantization models and two tokenization models. FIG. 29 is another schematic illustration of responding to two queries with two semantization models and a common tokenization model, where a sensing device responds to two queries with two semantization models and a common tokenization model.

A sensing device may receive both the first query token and the second query token and wake to enable its sensing gadget to sense the physical-world around itself into a sensed data. There are two options shown as follows:

Alternative #1: the sensing device may convert the sensed data into one common sensing semantic by one LLM or LLMs; and then the sensing device may tokenize the sensing semantic into the first sensing token in terms of the length of the first query token and tokenize the sensing semantic into the second sensing token in terms of the length of the second query token, in which the sensing device may use the first tokenization model to tokenize the sensing semantic into the first sensing token and the second tokenization model to tokenize the sensing semantic into the second sensing token (as shown in FIG. 26), or may use a common tokenization model to tokenize the sensing semantic into both the first sensing token and the second sensing token (as shown in FIG. 27); the sensing device may score the relevance between the first query token and the first sensing token and the relevance between the second query token and the second sensing token; the sensing device may tell whether or not the sensed data provides an enough relevance to the first query token if the first score of the relevance is greater than or equal to the first threshold, and the sensing device may tell whether or not the sensed data provides an enough relevance to the second query token if the second score of the relevance is greater than or equal to the second threshold; the sensing device may transmit at least one of the sensed data, sensing semantic or the first score of relevance if deciding the first score of relevance is high enough; the sensing device may transmit at least one of the sensed data, sensing semantic or the second score of relevance if deciding the second score of relevance is high enough;

Alternative #2: as shown in FIG. 27, the sensing device may convert the sensed data into the first sensing semantic by one LLM or LLMs and convert the same sensed data into the second sensing semantic by one LLM or LLMs; and then the sensing device may tokenize the first sensing semantic into the first sensing token in terms of the length of the first query token and tokenize the second sensing semantic into the second sensing token in terms of the length of the second query token, in which the sensing device may use the first tokenization model to tokenize the first sensing semantic into the first sensing token and the second tokenization model to tokenize the second sensing semantic into the second sensing token (as shown in FIG. 28), or may use a common tokenization model to tokenize the sensing semantic into both the first sensing token and the second sensing token (as shown in FIG. 29); the sensing device may score the relevance between the first query token and the first sensing token and the relevance between the second query token and the second sensing token; the sensing device may tell whether or not the sensed data provides an enough relevance to the first query token if the first score of the relevance is greater than or equal to the first threshold, and the sensing device may tell whether or not the sensed data provides an enough relevance to the second query token if the second score of the relevance is greater than or equal to the second threshold; the sensing device may transmit at least one of the sensed data, the first sensing semantic or the first score of relevance if deciding the first score of relevance is high enough; the sensing device may transmit at least one of the sensed data, the second sensing semantic or the second score of relevance if deciding the second score of relevance is high enough.

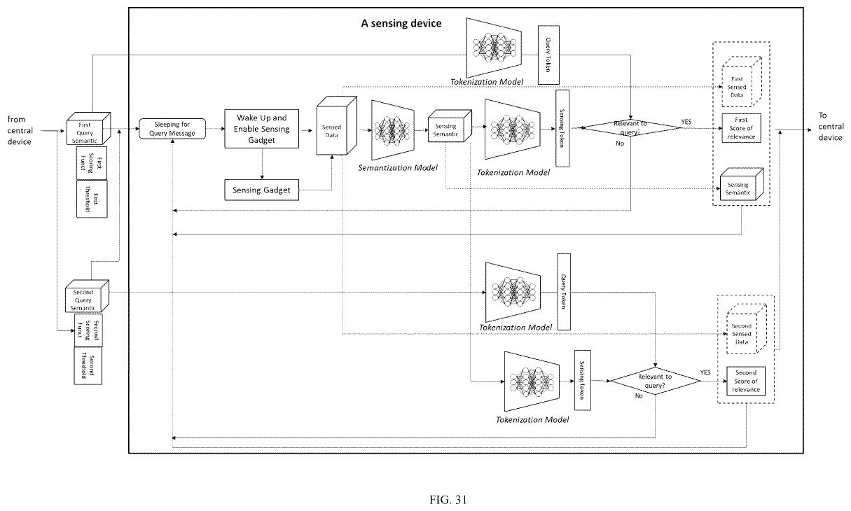

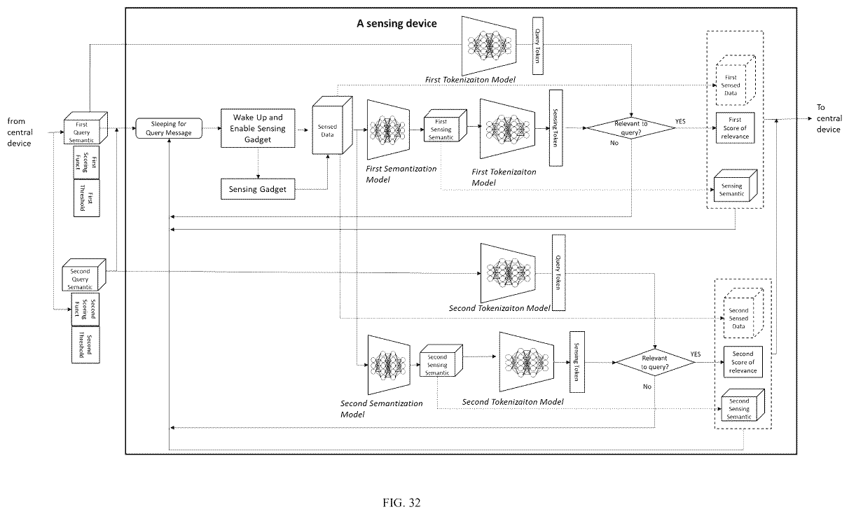

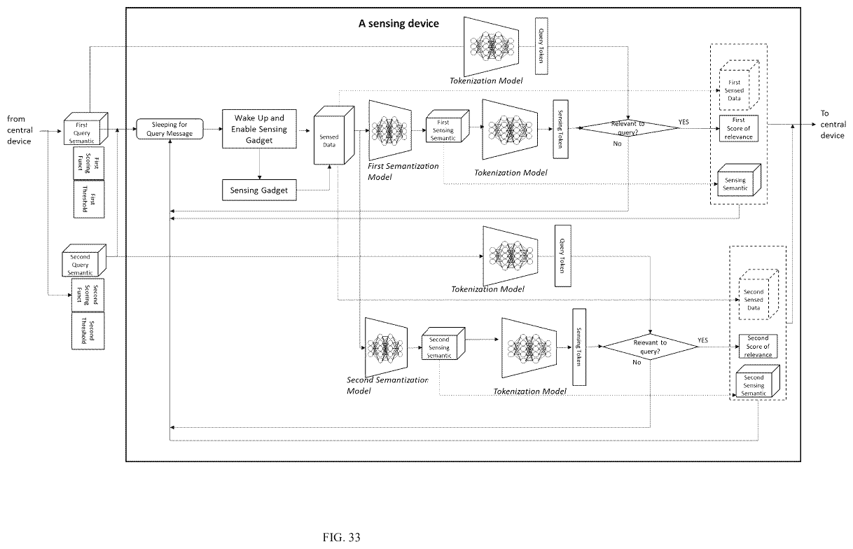

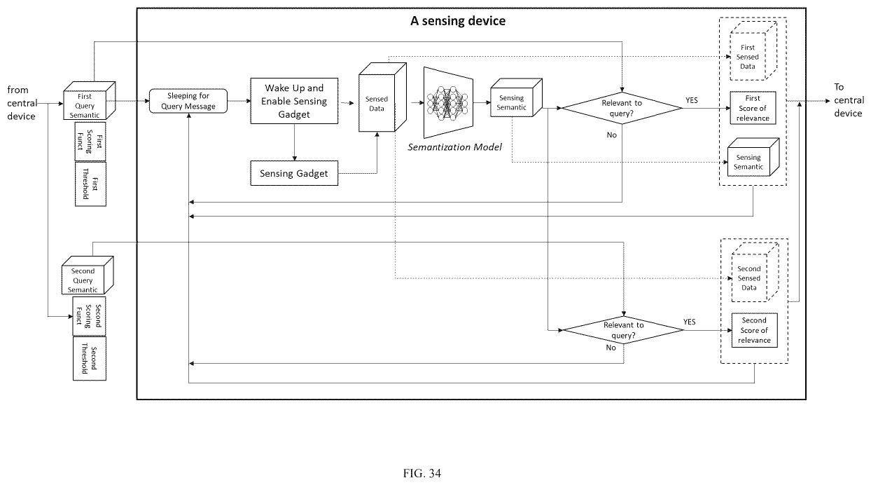

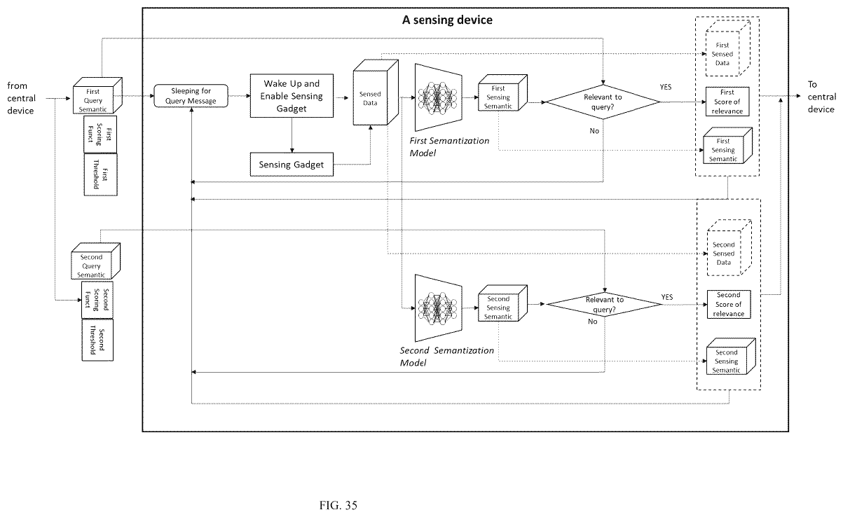

FIG. 30 is a schematic illustration of responding to two query semantics with a common semantization model and two different tokenization models, where a sensing device responds to two query semantics with a common semantization model and two different tokenization models. FIG. 31 is a schematic illustration of responding to two query semantics with a common semantization model and a common tokenization model, where a sensing device responds to two query semantics with a common semantization model and a common tokenization model. FIG. 32 is a schematic illustration of responding to two query semantics with two semantization models and two tokenization models, where a sensing device responds to two query semantics with two semantizations model and two tokenization models. FIG. 33 is a schematic illustration of responding to two query semantics with two semantization models and one tokenization model, where a sensing device responds to two query semantics with two semantizations model and one tokenization model. FIG. 34 is a schematic illustration of responding to two query semantics with one semantization model without tokenization model, where a sensing device responds to two query semantics with one semantization model without tokenization model. FIG. 35 is a schematic illustration of responding to two query semantics with two semantization models without tokenization model, where a sensing device responds to two query semantics with two semantization models without tokenization model.

A sensing device may receive both the first query semantic and the second query semantic and wake to enable its sensing gadget to sense the physical-world around itself into a sensed data. There are several options shown as follows:
Alternative #1: the sensing device may convert the sensed data into one common sensing semantic by one LLM or LLMs; and then the sensing device may tokenize the sensing semantic into the first sensing token and the first query semantic into the first query token, both tokens of which are with the same first length that the sensing device decides, while the sensing device may tokenize the sensing semantic into the second sensing token and the second query semantic into the second query token, both tokens of which are with the same second length that the sensing device decides, wherein the sensing device may use the first tokenization model to tokenize the sensing semantic into the first sensing token and the second tokenization model to tokenize the sensing semantic into the second sensing token (FIG. 30), or may use a common tokenization model to tokenize the sensing semantic into both the first sensing token and the second sensing token (FIG. 31); the sensing device may score the relevance between the first query token and the first sensing token and the relevance between the second query token and the second sensing token; the sensing device may tell whether or not the sensed data provides an enough relevance to the first query token if the first score of the relevance is greater than or equal to the first threshold, and the sensing device may tell whether or not the sensed data provides an enough relevance to the second query token if the second score of the relevance is greater than or equal to the second threshold; the sensing device may transmit at least one of the sensed data, sensing semantic or the first score of relevance if deciding the first score of relevance is high enough; the sensing device may transmit at least one of the sensed data, sensing semantic or the second score of relevance if deciding the second score of relevance is high enough;
Alternative #2: the sensing device may convert the sensed data into the first sensing semantic by one LLM or LLMs and convert the same sensed data into the second sensing semantic by one LLM or LLMs; and tokenize the first sensing semantic into the first sensing token and the first query semantic into the first query token, both tokens of which are with the same first length that the sensing device decides, while the sensing device may tokenize the second sensing semantic into the second sensing token and the second query semantic into the second query token, both tokens of which are with the same second length that the sensing device decides, where the sensing device may use the first tokenization model to tokenize the first sensing semantic into the first sensing token and the second tokenization model to tokenize the second sensing semantic into the second sensing token (FIG. 32), or may use a common tokenization model (FIG. 33) to tokenize the first and second sensing semantics into both the first sensing token and the second sensing token; the sensing device may score the relevance between the first query token and the first sensing token and the relevance between the second query token and the second sensing token; the sensing device may tell whether or not the sensed data provides an enough relevance to the first query token if the first score of the relevance is greater than or equal to the first threshold, and the sensing device may tell whether or not the sensed data provides an enough relevance to the second query token if the second score of the relevance is greater than or equal to the second threshold; the sensing device may transmit at least one of the sensed data, the first sensing semantic or the first score of relevance if deciding the first score of relevance is high enough; the sensing device may transmit at least one of the sensed data, the second sensing semantic or the second score of relevance if deciding the second score of relevance is high enough;
Alternative #3 (FIG. 34): the sensing device may convert the sensed data into one common sensing semantic by one LLM or LLMs; and then the sensing device may score the relevance between the first query semantic and the sensing semantic and the relevance between the second query semantic and the sensing semantic; the sensing device may tell whether or not the sensed data provides an enough relevance to the first query semantic if the first score of the relevance is greater than or equal to the first threshold, and the sensing device may tell whether or not the sensed data provides an enough relevance to the second query semantic if the second score of the relevance is greater than or equal to the second threshold; the sensing device may transmit at least one of the sensed data, the sensing semantic or the first score of relevance if deciding the first score of relevance is high enough; the sensing device may transmit at least one of the sensed data, the sensing semantic or the second score of relevance if deciding the second score of relevance is high enough;
Alternative #4 (FIG. 35): the sensing device may convert the sensed data into the first sensing semantic by one LLM or LLMs and convert the same sensed data into the second sensing semantic by one LLM or LLMs; and then the sensing device may score the relevance between the first query semantic and the first sensing semantic and the relevance between the second query semantic and the second sensing semantic; the sensing device may tell whether or not the sensed data provides an enough relevance to the first query semantic if the first score of the relevance is greater than or equal to the first threshold, and the sensing device may tell whether or not the sensed data provides an enough relevance to the second query semantic if the second score of the relevance is greater than or equal to the second threshold; the sensing device may transmit at least one of the sensed data, the first sensing semantic or the first score of relevance if deciding the first score of relevance is high enough; the sensing device may transmit at least one of the sensed data, the second sensing semantic or the second score of relevance if deciding the second score of relevance is high enough.

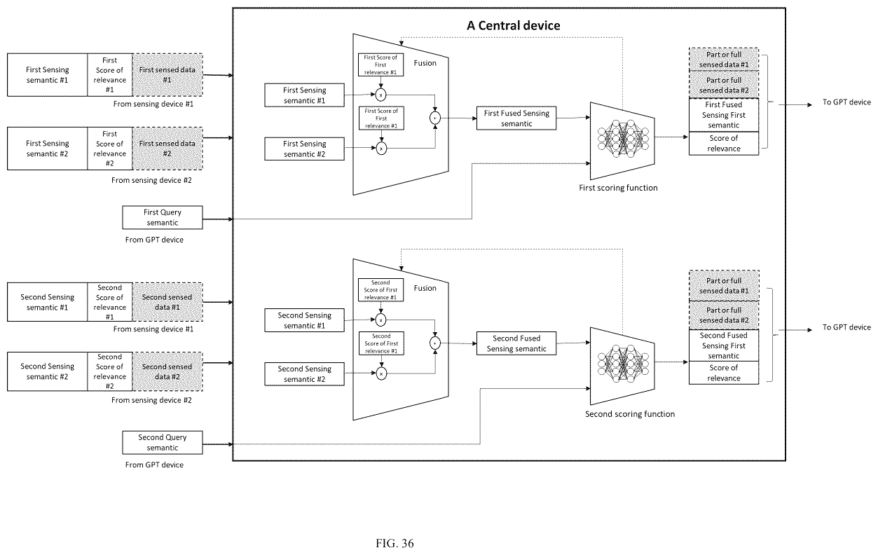

FIG. 36 is a schematic illustration of processing two sensing semantics independently, where a central device processes the two sensing semantics independently.

If the central device receives a number of the first sensing semantics plus the first scores of relevance and a number of the second sensing semantics plus the second scores of relevance, the central device may fuse these first sensing semantics according to their first scores of relevance into the first fused sensing semantic and the central device may fuse these second sensing semantics according to their second scores of relevance into the second fused sensing semantic; the central device may score the first fused sensing semantic by measuring the relevance between the first fused semantic and the first query semantic, and score the second fused sensing semantic by measuring the relevance between the second fused sensing semantic and the second query semantic; the central device may transmit the first fused sensing semantic with the first score of relevance to the first GPT device and transmit the second fused sensing semantic with the second score of relevance to the second GPT device; as shown in FIG. 36.

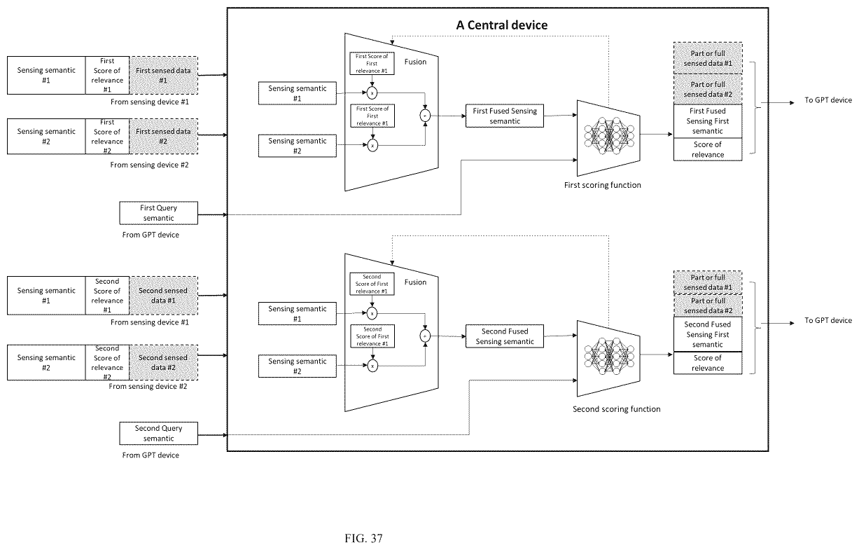

FIG. 37 is a schematic illustration of processing one sensing semantic but with two tasks independently, where a central device processes the one or more sensing semantics but with two tasks independently.

If the central device receives a number of the sensing semantics plus the first scores of relevance and the second scores of relevance, the central device may fuse these sensing semantics according to their first scores of relevance into the first fused sensing semantic and the central device may fuse the second sensing semantics according to their second scores of relevance into the second fused sensing semantic; the central device may score the first fused sensing semantic by measuring the relevance between the first fused semantic and the first query semantic, and score the second fused sensing semantic by measuring the relevance between the second fused sensing semantic and the second query semantic; the central device may transmit the first fused sensing semantic with the first score of relevance to the first GPT device and transmit the second fused sensing semantic with the second score of relevance to the second GPT device; as shown in FIG. 37.

The first GPT device may receive the first fused sensing semantic and the first score of relevance to the first query semantic; the first GPT device may de-semantize the first fused sensing semantic into the first sensing message; the first GPT device may input the first sensing message into the LLM(s) to inference to generate the next first query message; optionally, the first GPT device may input the first sensing message plus the first score of relevance to the LLM(s).

The second GPT device may receive the second fused sensing semantic and the second score of relevance to the second query semantic; the second GPT device may de-semantize the second fused sensing semantic into the second sensing message; the second GPT device may input the second sensing message into the LLM(s) to inference to generate the next second query message; optionally, the second GPT device may input the second sensing message plus the second score of relevance to the LLM(s).

Next, examples of products related to the sensing communication methods will be described.

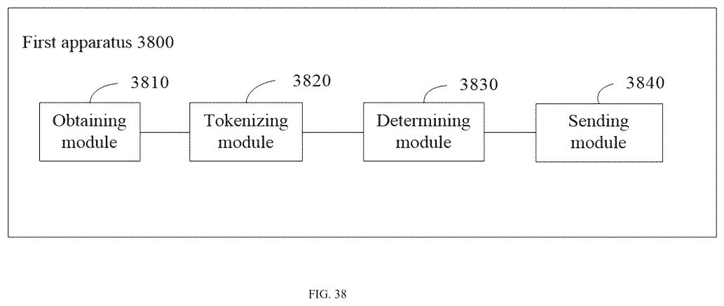

FIG. 38 is a schematic structural diagram of a first apparatus according to one or more example embodiments of the present disclosure.

As shown in FIG. 38, the first apparatus 3800 includes: an obtaining module 3810, configured to obtain a tokenization configuration; and obtain at least one query message; a tokenizing module 3820, configured to tokenize at least one sensing semantic to at least one sensing token based on the tokenization configuration, where each of the at least one sensing semantic is tokenized to a corresponding sensing token; a determining module 3830, configured to determine, from the at least one sensing token, one or more sensing tokens matching one or more query messages; and a sending module 3840, configured to send a sensing result, where the sensing result includes at least one piece of sensed data and/or at least one sensing semantic corresponding to the determined one or more sensing tokens.

In a possible implementation, the tokenization configuration includes at least one of: at least one tokenization model; at least one function; at least one projection matrix; at least one graph-based or topology-based pruning; or at least one compression approach.

In a possible implementation, at least one of a set of tokenization models, a set of functions, a set of projection matrixes, a set of graph-based or topology-based pruning, or a set of compression approaches are configured for multiple tasks, and/or at least one of a set of tokenization models, a set of functions, a set of projection matrixes, a set of graph-based or topology-based pruning, or a set of compression approaches are configured for multiple modalities, and/or at least one of a set of tokenization models, a set of functions, a set of projection matrixes, a set of graph-based or topology-based pruning, or a set of compression approaches are configured for multiple combinations of a task and a modality.

In a possible implementation, each tokenization model of the set of tokenization models, each function of the set of functions, each projection matrix of the set of projection matrix, each graph-based or topology-based pruning of the set of graph-based or topology-based pruning, or each compression approach of the set of compression approaches corresponds to at least one identifier indicating a task identifier, a modality identifier, or both a task identifier and a modality identifier.

In a possible implementation, the tokenization configuration includes at least one tokenization model; and the tokenizing module 3820 is further configured to tokenize each of one or more sensing semantics to a corresponding sensing token based on a corresponding one of the at least one tokenization model.

In a possible implementation, each of the at least one tokenization model is a deep learning model; and the tokenizing module 3820 is further configured to input each of one or more sensing semantics into a corresponding one of the at least one deep learning model to obtain a corresponding sensing token.

In a possible implementation, the tokenization configuration includes at least one function; and the tokenizing module 3820 is further configured to apply, with each of one or more sensing semantics as a function parameter, a corresponding one of the at least one function to obtain a corresponding sensing token.

In a possible implementation, the tokenization configuration includes at least one projection matrix; and the tokenizing module 3820 is further configured to project each of one or more sensing semantics onto a sub-space defined by a corresponding one of the at least one projection matrix based on a high-dimensional matrix multiplication to obtain a corresponding sensing token.

In a possible implementation, each of the at least one sensing semantic is represented by a graph or topology, and the tokenization configuration includes at least one graph-based or topology-based pruning, and the tokenizing module 3820 is further configured to select a subgraph, or a partial topology, or partial parameters from the graph or topology represented by each of one or more sensing semantics based on an approach or criterion defined by a corresponding one of the at least one graph-based or topology-based pruning, to obtain a corresponding sensing token.

In a possible implementation, the tokenization configuration includes at least one compression approach, and the tokenizing module 3820 is further configured to compress, based on a corresponding one of at least one compression approach, each of one or more sensing semantics to obtain a corresponding sensing token, where the compression approach includes at least one of transformation, quantization, coefficients selection, or entropy coding.

In a possible implementation, the obtaining module 3810 is further configured to: obtain the tokenization configuration via a broadcast message; obtain the tokenization configuration via a multicast configuration targeted to a group of first apparatuses; or obtain the tokenization configuration via a dedicated message to a first apparatus.

In a possible implementation, each of the at least one query message corresponds to a task, a modality, or a combination of a task and a modality.

In a possible implementation, each of the at least one query message includes at least one identifier, where the at least one identifier indicates a task identifier, a modality identifier, or both a task identifier and a modality identifier.

In a possible implementation, the obtaining module 3810 is further configured to obtain, for each of the at least one query message and based on the at least one identifier for the each of the at least one query message, at least one tokenization model matching the at least one identifier in the tokenization configuration, at least one function matching the at least one identifier in the tokenization configuration, at least one projection matrix matching the at least one identifier in the tokenization configuration, at least one graph-based or topology-based pruning matching the at least one identifier in the tokenization configuration, or at least one compression approach matching the at least one identifier in the tokenization configuration.

In a possible implementation, the at least one piece of sensed data includes at least one piece of raw sensed data, half raw sensed data, or compressed sensed data.

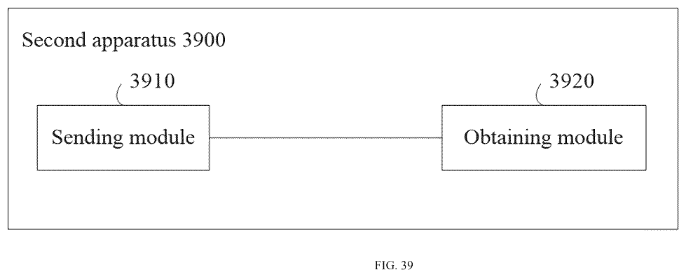

FIG. 39 is a schematic structural diagram of a second apparatus according to one or more example embodiments of the present disclosure.

As shown in FIG. 39, the second apparatus 3900 includes: a sending module 3910, configured to: send a tokenization configuration; and sending at least one query message; and an obtaining module 3920, configured to: obtain one or more sensing results, where each of the one or more sensing results includes at least one piece of sensed data and/or at least one sensing semantic corresponding to at least one sensing token that is tokenized from at least one sensing semantic based on the tokenization configuration and matches one or more query messages, where each of the at least one sensing semantic is tokenized to a corresponding sensing token.

In a possible implementation, the tokenization configuration includes at least one of: at least one tokenization model; at least one function; at least one projection matrix; at least one graph-based or topology-based pruning; or at least one compression approach.

In a possible implementation, at least one of a set of tokenization models, a set of functions, a set of projection matrixes, a set of graph-based or topology-based pruning, or a set of compression approaches are configured for multiple tasks, and/or at least one of a set of tokenization models, a set of functions, a set of projection matrixes, a set of graph-based or topology-based pruning, or a set of compression approaches are configured for multiple modalities, and/or at least one of a set of tokenization models, a set of functions, a set of projection matrixes, a set of graph-based or topology-based pruning, or a set of compression approaches are configured for multiple combinations of a task and a modality.

In a possible implementation, each tokenization model of the set of tokenization models, each function of the set of functions, each projection matrix of the set of projection matrix, each graph-based or topology-based pruning of the set of graph-based or topology-based pruning, or each compression approach of the set of compression approaches corresponds to at least one identifier indicating a task identifier, a modality identifier, or both a task identifier and a modality identifier.

In a possible implementation, the tokenization configuration includes at least one tokenization model, and each of one or more sensing tokens is tokenized from a corresponding sensing semantic based on a corresponding one of the at least one tokenization model.

In a possible implementation, each of the at least one tokenization model is a deep learning model, and each of one or more sensing tokens is tokenized from a corresponding sensing semantic by inputting the corresponding sensing semantic into corresponding one of at least one deep learning model to obtain the each of the at least one sensing token.

In a possible implementation, the tokenization configuration includes at least one function, and each of one or more sensing tokens is tokenized from a corresponding sensing semantic by applying a corresponding one of at least one function with the corresponding sensing semantic as a function parameter to obtain the each of the at least one sensing token.

In a possible implementation, the tokenization configuration includes at least one projection matrix, and each of one or more sensing tokens is tokenized from a corresponding sensing semantic by projecting the corresponding sensing semantic onto a sub-space defined by a corresponding one of the at least one projection matrix based on a high-dimensional matrix multiplication to obtain the each of the at least one sensing token.

In a possible implementation, each of the at least one sensing semantic is represented by a graph or topology, and the tokenization configuration includes at least one graph-based or topology-based pruning, and each of one or more sensing tokens is tokenized from a corresponding sensing semantic by selecting a subgraph, or a partial topology, or partial parameters from the graph or topology represented by each of the at least one sensing semantic based on an approach or criterion defined by a corresponding one of the at least one graph-based or topology-based pruning, to obtain the each of the at least one sensing token.

In a possible implementation, the tokenization configuration includes at least one compression approach, and each of one or more sensing tokens is tokenized from a corresponding sensing semantic by compressing, using a corresponding one of the at least one compression approach, the corresponding sensing semantic to obtain the each of the at least one sensing token, where the compression approach includes at least one of transformation, quantization, coefficients selection, or entropy coding.

In a possible implementation, the sending module 3910 is further configured to: send the tokenization configuration via a broadcast message; send the tokenization configuration via a multicast configuration targeted to a group of first apparatuses; or send the tokenization configuration via a dedicated message to a first apparatus.

In a possible implementation, each of the at least one query message corresponds to a task, a modality, or a combination of a task and a modality.

In a possible implementation, each of the at least one query message includes at least one identifier, where the at least one identifier indicates a task identifier, a modality identifier, or both a task identifier and a modality identifier.

In a possible implementation, the at least one identifier for the each of the at least one query message is used for a first apparatus to obtaining, for each of the at least one query message, at least one tokenization model matching the at least one identifier in the tokenization configuration, at least one function matching the at least one identifier in the tokenization configuration, at least one projection matrix matching the at least one identifier in the tokenization configuration, at least one graph-based or topology-based pruning matching the at least one identifier in the tokenization configuration, or at least one compression approach matching the at least one identifier in the tokenization configuration.

In a possible implementation, the at least one piece of sensed data includes at least one piece of raw sensed data, half raw sensed data, or compressed sensed data.

The second apparatus may be applied to the above second apparatus such as the central device as described in the above possible method implementations. It should be understood by a person skilled in the art that the relevant description of the above modules in these possible implementations of the present disclosure may be understood with reference to the relevant description of the sensing communication method in these possible implementations of the present disclosure. The technical effect achieved by the above second apparatus is similar as that achieved by the above possible method implementations, which is not repeated herein.

A possible implementation of the present disclosure provides a third apparatus including processing circuitry for executing any of the above corresponding sensing communication methods at the first apparatus side, which is not repeated herein.

A possible implementation of the present disclosure provides a fourth apparatus including processing circuitry for executing any of the above corresponding sensing communication methods at the second apparatus side, which is not repeated herein.

A possible implementation of the present disclosure provides a wireless communication system, including at least one first apparatus for executing any of the above corresponding sensing communication methods at the first apparatus side or at least one third apparatus for executing any of the above corresponding sensing communication methods at the first apparatus side; at least one second apparatus for executing any of the above corresponding sensing communication methods at the second apparatus side or at least one fourth apparatus for executing any of the above corresponding sensing communication methods at the second apparatus side; and at least one fifth apparatus, where each of the at least one fifth apparatus includes: a sending module, configured to send at least one query message to the at least one second apparatus; and an obtaining module, configured to obtain at least one fused sensing result sent by the at least one second apparatus, where the at least one fused sensing result is generated based on one or more sensing results. The above method is not repeated herein.

A possible implementation of the present disclosure provides a wireless communication system including: a first processing circuitry for executing any of the above corresponding sensing communication methods at the first apparatus side; a second processing circuitry for executing any of the above corresponding sensing communication methods at the second apparatus side; and a third processing circuitry for executing following steps: sending at least one query message to the second processing circuitry; and obtaining at least one fused sensing result sent by the second processing circuitry, where the at least one fused sensing result is generated based on one or more sensing results. The above method is not repeated herein.

A possible implementation of the present disclosure provides a computer-readable storage medium storing computer execution instructions which, when executed by a processor, cause the processor to execute any of the above sensing communication methods, which is not repeated herein.

A possible implementation of the present disclosure provides a computer program product including computer execution instructions which, when executed by a processor, causes the processor to execute any of the above sensing communication methods, which is not repeated herein.

A method, apparatus and system for semantic token calculation is provided in present disclosure.

Some aspects of the present disclosure relate to a scheme of a semantic-based communication to manage and schedule a large number of sensing devices, in which the sensing devices may belong to different types. The query semantics are goal-oriented and only the sensing device whose sensed data has sufficient relevance with the semantic message(s) would response and transmit their sensed data that are preferably in semantic form too.

Some aspects of the present disclosure relate to a scheme of a collective semantic token-based scheduling over a large number of sensing devices rather than one-to-one individual scheduling.

Some aspects of the present disclosure relate to a scheme of using the large-language-model (LLM) to turn query and sensed data into a common semantic domain on which they can be easily compared to each other and fused.

The above one or more aspects of the present disclosure may have at least one of the following benefits:
scheduling may be task-oriented or goal-oriented; only the sensing devices that have contributions to a scheduled task or goal will response and transmit their sensed data;
privacy may be protected: both the task, goal, or query and sensed data are well protected; no raw data or minimum raw data or message is transmitted over the air;
forward compatible: semantic-based sensing system in this disclosure may be forward compatible in a sense that any new sensing mechanism can be supported.

In some aspects of the present disclosure, there is provided a computer program including instructions. The instructions, when executed by a processor, may cause the processor to implement the method of the present disclosure.

In some aspects of the present disclosure, there is provided a non-transitory computer-readable medium storing instructions, the instructions, when executed by a processor, may cause the processor to implement the method of the present disclosure.

In some aspects of the present disclosure, there is provided an apparatus/chipset system including means to implement the method implemented by the sensing device of the present disclosure.

In some aspects of the present disclosure, there is provided an apparatus/chipset system including means to implement the method implemented by the central device of the present disclosure.

In some aspects of the present disclosure, there is provided an apparatus/chipset system including means to implement the method implemented by the GPT device of the present disclosure.

In some aspects of the present disclosure, there is provided a system including at least two of an apparatus in the sensing device of the present disclosure, an apparatus in the central device of the present disclosure and an apparatus in the GPT device of the present disclosure.

In some aspects of the present disclosure, there is provided an apparatus/chipset system including at least one processor executing instructions stored in a computer-readable medium to implement the method implemented by the sensing device of the present disclosure.

In some aspects of the present disclosure, there is provided an apparatus/chipset system including at least one processor executing instructions stored in a computer-readable medium to implement the method implemented by the central device of the present disclosure.

In some aspects of the present disclosure, there is provided an apparatus/chipset system including at least one processor executing instructions stored in a computer-readable medium to implement the method implemented by the GPT device of the present disclosure.

### Example Concepts of Some Terms

Message: a payload in a natural language, e.g., English, French, or Chinese;
Query message: a query sentence in a natural language;
Sensing message: a description about an observation or sensed data in a natural language;
Semantic: a vector, a matrix, a tensor of scalars to embed a message;
Query semantic: a semantic that embeds a query message;
Sensing semantic: a semantic that embeds a sensing message;
Token: a vector of scalars encoded from a semantic;
Query token: a token that is encoded from a query semantic;
Sensing token: a token that is encoded from a sensing semantic;
GPT device: a device that runs over generative AI model or models to generate one query message or messages given a sensing message or messages;
Central device: a device as BS that connects a plurality of terminal devices via radio access in DL and UL, and connects with the core network via backbone network;
Sensing device: a device as terminal that connects to one BS or BSs and that is equipped with the sensing gadget to measure data of interest near it.

Please note that the different embodiments may be implemented separately or combined. Although a combination of features is shown in the illustrated embodiments, not all of them need to be combined to realize the benefits of various embodiments of this disclosure. In other words, a system or method designed according to an embodiment of this disclosure will not necessarily include all of the features shown in any one of the Figures or all of the portions schematically shown in the Figures. Moreover, selected features of one example embodiment may be combined with selected features of other example embodiments.

Although this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

Although the present disclosure describes methods and processes with steps in a certain order, one or more steps of the methods and processes may be omitted or altered as appropriate. One or more steps may take place in an order other than that in which they are described, as appropriate.

Note that the expression “at least one of A or B,” as used herein, is interchangeable with the expression “A and/or B.” It refers to a list in which you may select A or B or both A and B. Similarly, “at least one of A, B, or C,” as used herein, is interchangeable with “A and/or B and/or C” or “A, B, and/or C.” It refers to a list in which you may select: A or B or C, or both A and B, or both A and C, or both B and C, or all of A, B and C. The same principle applies for longer lists having a same format.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable storage medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein. The machine-executable instructions may be in the form of code sequences, configuration information, or other data, which, when executed, cause a machine (e.g., a processor or other processing device) to perform steps in a method according to examples of the present disclosure.

All values and sub-ranges within disclosed ranges are also disclosed. Also, although the systems, devices and processes disclosed and shown herein may include a specific number of elements/components, the systems, devices and assemblies could be modified to include additional or fewer of such elements/components. For example, although any of the elements/components disclosed may be referenced as being singular, the possible implementations disclosed herein could be modified to include a plurality of such elements/components. The subject matter described herein intends to cover and embrace all suitable changes in technology.

1. A method, comprising:
obtaining a tokenization configuration;
obtaining at least one query message;
tokenizing at least one sensing semantic to at least one sensing token based on the tokenization configuration, wherein each sensing semantic of the at least one sensing semantic is tokenized to a corresponding sensing token of the at least one sensing token;
determining, from the at least one sensing token, one or more sensing tokens matching one or more query messages of the at least one query message; and
sending a sensing result, wherein the sensing result indicates at least one of:
at least one piece of sensed data or one or more sensing semantics corresponding to the one or more sensing tokens.

2. The method according to claim 1, wherein the tokenization configuration indicates at least one of:
at least one tokenization model;
at least one function;
at least one projection matrix;
at least one graph-based or topology-based pruning; or
at least one compression approach.

3. The method according to claim 2, wherein at least one of a set of tokenization models, a set of functions, a set of projection matrixes, a set of graph-based or topology-based prunings, or a set of compression approaches is configured for at least one of multiple tasks, multiple modalities, or multiple combinations of a task and a modality.

4. The method according to claim 3, wherein each tokenization model of the set of tokenization models, each function of the set of functions, each projection matrix of the set of projection matrixes, each graph-based or topology-based pruning of the set of graph-based or topology-based prunings, or each compression approach of the set of compression approaches corresponds to at least one respective identifier indicating a respective task identifier, a respective modality identifier, or both the respective task identifier and the respective modality identifier.

5. The method according to claim 2, wherein the tokenization configuration indicates the at least one tokenization model, and
the tokenizing the at least one sensing semantic to the at least one sensing token based on the tokenization configuration comprises:
tokenizing each sensing semantic of the one or more sensing semantics to the corresponding sensing token based on a corresponding tokenization model of the at least one tokenization model.

6. The method according to claim 5, wherein each tokenization model of the at least one tokenization model is a corresponding deep learning model of at least one deep learning model, and
the tokenizing the at least one sensing semantic to the at least one sensing token based on the at least one tokenization model comprises:
inputting each sensing semantic of the one or more sensing semantics into the corresponding deep learning model of the at least one deep learning model to obtain the corresponding sensing token.

7. An apparatus comprising:
at least one processor coupled with a memory storing instructions, wherein when the instructions executed by the at least one processor, the apparatus is caused to perform:
obtaining a tokenization configuration; and obtain at least one query message;
tokenizing at least one sensing semantic to at least one sensing token based on the tokenization configuration, wherein each sensing semantic of the at least one sensing semantic is tokenized to a corresponding sensing token of the at least one sensing token;
determining, from the at least one sensing token, one or more sensing tokens matching one or more query messages of the at least one query message; and
sending a sensing result, wherein the sensing result indicates at least one of:
at least one piece of sensed data or one or more sensing semantics corresponding to the one or more sensing tokens.

8. The apparatus according to claim 7, wherein the tokenization configuration indicates at least one of:
at least one tokenization model;
at least one function;
at least one projection matrix;
at least one graph-based or topology-based pruning; or
at least one compression approach.

9. The apparatus according to claim 8, wherein at least one of a set of tokenization models, a set of functions, a set of projection matrixes, a set of graph-based or topology-based pruning, or a set of compression approaches is configured for at least one of multiple tasks, multiple modalities, or multiple combinations of a task and a modality.

10. The apparatus according to claim 9, wherein each tokenization model of the set of tokenization models, each function of the set of functions, each projection matrix of the set of projection matrixes, each graph-based or topology-based pruning of the set of graph-based or topology-based prunings, or each compression approach of the set of compression approaches corresponds to at least one respective identifier indicating a respective task identifier, a respective modality identifier, or both the respective task identifier and the respective modality identifier.

11. The apparatus according to claim 8, wherein the tokenization configuration indicates the at least one tokenization model, and
the tokenizing the at least one sensing semantic to the at least one sensing token based on the tokenization configuration comprises:
tokenizing each sensing semantic of the one or more sensing semantics to the corresponding sensing token based on a corresponding tokenization model of the at least one tokenization model.

12. The apparatus according to claim 11, wherein each tokenization model of the at least one tokenization model is a corresponding deep learning model of at least one deep learning model, and
the tokenizing the at least one sensing semantic to the at least one sensing token based on the at least one tokenization model comprises:
inputting each sensing semantic of the one or more sensing semantics into the corresponding deep learning model of the at least one deep learning model to obtain the corresponding sensing token.

13. The apparatus according to claim 8, wherein the tokenization configuration indicates the at least one function, and
the tokenizing the at least one sensing semantic to the at least one sensing token based on the at least one tokenization model comprises:
applying, with each sensing semantic of the one or more sensing semantics as a function parameter, a corresponding function of the at least one function to obtain the corresponding sensing token.

14. A apparatus, comprising:
at least one processor coupled with a memory storing instructions, wherein when the instructions executed by the at least one processor, the apparatus is caused to perform:
sending a tokenization configuration;
sending at least one query message; and
obtaining one or more sensing results, wherein each sensing result of the one or more sensing results comprises at least one of at least one piece of sensed data or at least one sensing semantic corresponding to at least one sensing token that is tokenized from at least one sensing semantic based on the tokenization configuration and matches one or more query messages of the at least one query message, wherein each sensing semantic of the at least one sensing semantic is tokenized to a corresponding sensing token.

15. The apparatus according to claim 14, wherein the tokenization configuration indicates at least one of:
at least one tokenization model;
at least one function;
at least one projection matrix;
at least one graph-based or topology-based pruning; or
at least one compression approach.

16. The apparatus according to claim 15, wherein at least one of a set of tokenization models, a set of functions, a set of projection matrixes, a set of graph-based or topology-based prunings, or a set of compression approaches is configured for at least one of multiple tasks, multiple modalities, or multiple combinations of a task and a modality.

17. The apparatus according to claim 16, wherein each tokenization model of the set of tokenization models, each function of the set of functions, each projection matrix of the set of projection matrixes, each graph-based or topology-based pruning of the set of graph-based or topology-based prunings, or each compression approach of the set of compression approaches corresponds to at least one respective identifier indicating a respective task identifier, a respective modality identifier, or both the respective task identifier and the respective modality identifier.

18. The apparatus according to claim 15, wherein the tokenization configuration indicates the at least one tokenization model, and each sensing token of one or more sensing tokens is tokenized from a corresponding sensing semantic based on a corresponding tokenization model of the at least one tokenization model.

19. The apparatus according to claim 18, wherein each tokenization model of the at least one tokenization model is a corresponding deep learning model of at least one deep learning model, and each sensing token of the one or more sensing tokens is tokenized from the corresponding sensing semantic by inputting the corresponding sensing semantic into the corresponding deep learning model of the at least one deep learning model to obtain each sensing token of the at least one sensing token.

20. The apparatus according to claim 15, wherein the tokenization configuration indicates the at least one function, and each sensing token of one or more sensing tokens is tokenized from a corresponding sensing semantic by applying a corresponding function of the at least one function with the corresponding sensing semantic as a function parameter to obtain each sensing token of the at least one sensing token.
